(19) United States
(12) Patent Application Publication
(10) Pub. No.: US 2012/0005549 A1
(43) Pub. Date: Jan. 5, 2012

(54) TRANSFER APPARATUS, TRANSFER PROGRAM, AND TRANSFER METHOD

(75) Inventors: Atsushi ICHIKI, Kawasaki (JP); Ryuta TANAKA, Kawasaki (JP)

(73) Assignee: FUJITSU LIMITED, Kawasaki-shi (JP)

(21) Appl. No.: 13/169,161

(22) Filed: Jun. 27, 2011

(30) Foreign Application Priority Data
Jun. 30, 2010 (JP) 2010-149866

(51) Int. Cl. H03M 13/05; G06F 11/10; H04L 1/18; G06F 11/14

(52) U.S. Cl. 714/748; 714/776; 714/E11.032; 714/E11.113

(57) ABSTRACT

A transfer apparatus includes: a receiver to receive one of an error correction packet and a data packet, the error correction packet for recovering the data packet through error correction, and the data packet having protective coverage information written thereon, the protective coverage information identifying a protective coverage on the data packet recoverable through an error correction of the error correction packet; an updater to update the protective coverage information in accordance with an order of reception of the data packets received by the receiver unit; a generator to generate an error correction packet of the data packet identified by new protective coverage information updated by the updater unit; and a transmitter to transmit the data packet having the protective coverage information updated by the updater unit, and the error correction packet generated by the generator unit.

### CROSS-REFERENCE TO RELATED APPLICATIONS

This application is based upon and claims the benefit of priority of the prior Japanese Patent Application No. 2010-149866, filed on Jun. 30, 2010, the entire contents of which are incorporated herein by reference.

### FIELD

Embodiments of the present invention relate to a transfer apparatus and a transfer method.

### BACKGROUND

A variety of communication techniques for transferring data are known. In one example, media data such as video or audio (sound) is transferred through a peer-to-peer (P2P) communication system or an application layer multicast (ALM) communication system. A transfer system in the P2P or the ALM includes transfer apparatuses called nodes that are arranged in a tree-like configuration. In the transfer system, data is successively relayed from the node at the tree top to nodes at lower layers. A vast amount of data is thus delivered.

Such a relay transfer is subject to a delay referred to as a relay delay. The relay delay occurs because data packets received from a node at an upper layer are accumulated on a buffer until the data packets are transferred to a lower node. This operation is performed to absorb a transfer jitter taking place between nodes. The relay delay increases as the number layers increases.

If a real-time transfer is performed, the data packet is preferably transferred to a lower layer as quick as possible. To this end, an error correction technique controlling a retransmission caused by a packet loss is used. Forward error correction (FEC) is available as one of the error correction techniques. In the forward error correction, abundant data is added to the data packet before the data packet is transmitted, and data failing to reach a receiver side is recovered from the abundant data.

In the forward error correction, the uppermost node inserts FEC packets in data packets when the data packets are transmitted to a lower-layer node. Such an FEC packet includes protective coverage information identifying a range of the data packets that are a protection target of an error correction operation of the FEC packet. A node at a lower layer references the protective coverage information, and recovers the data packet using the FEC packet having as the protection target the data packet if the data packet is missing. For example, WO2005-013542 (Feb. 10, 2005) describes such a technique.

If the media data is transferred at a constant bit rate (CBR), the FEC packets are inserted every constant number of data packets. The insertion intervals of the FEC packets remain constant. If the media data is transferred at a variable bit rate (VBR), the FEC packets are inserted every constant period of time. The insertion intervals of the FEC packets are variable. If the FEC packets are inserted at constant data packet intervals, the lower the transfer rate, the larger the transfer delay. For example, Japanese Laid-open Patent Publication No. 2008-11096 (Jan. 17, 2008) describes such a technique.

### SUMMARY

A transfer apparatus includes: a receiver to receive one of an error correction packet and a data packet, the error correction packet for recovering the data packet through error correction, and the data packet having protective coverage information written thereon, the protective coverage information identifying a protective coverage on the data packet recoverable through an error correction of the error correction packet; an updater to update the protective coverage information in accordance with an order of reception of the data packets received by the receiver unit; a generator to generate an error correction packet of the data packet identified by new protective coverage information updated by the updater unit; and a transmitter to transmit the data packet having the protective coverage information updated by the updater unit, and the error correction packet generated by the generator unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawings of which:

FIG. 1 is a block diagram illustrating a configuration of a transfer apparatus of a first embodiment;

FIG. 2 illustrates an example of a relay transfer process executed in a transfer system of a second embodiment;

FIG. 3 illustrates an example of the structure of an RTP header;

FIG. 4 illustrates an example of the structure of an FEC packet;

FIG. 5 illustrates an example of the structure of an FEC header;

FIG. 6 illustrates a generation process of parity information of the FEC packet;

FIG. 7 is a block diagram illustrating a configuration of a transfer apparatus of the second embodiment;

FIG. 8 illustrates an example of FEC packet information added by an FEC packet information adder unit;

FIG. 9 illustrates an example of FEC packet information included in an RTP packet;

FIG. 10 is a flowchart illustrating a packet reception process of the second embodiment;

FIG. 11 is a continuation of the flowchart of FIG. 10;

FIG. 12 is a continuation of the flowchart of FIG. 10;

FIG. 13 is a continuation of the flowchart of FIG. 10;

FIG. 14 illustrates an example of a data transfer process performed by the transfer apparatus of the second embodiment;

FIG. 15 illustrates an example of a data transfer process performed by the transfer apparatus of the second embodiment;

FIG. 16 is a block diagram illustrating a configuration of a transfer apparatus of a third embodiment;

FIG. 17 illustrates an example of the FEC packet information included in the RTP packet;

FIG. 18 is a flowchart of a packet reception process of the third embodiment;

FIG. 19 is a continuation of the flowchart of FIG. 18;

FIG. 20 is a continuation of the flowchart of FIG. 18;

FIG. 21 is a continuation of the flowchart of FIG. 18;

FIG. 22 illustrates an example of a data transfer process preformed by the transfer apparatus of the third embodiment;

FIG. 23 illustrates an example of a data transfer process performed by the transfer apparatus of the third embodiment;

FIG. 24 illustrates an example of a computer executing a transfer program of a fourth embodiment;

FIG. 25 illustrates an example of a transfer delay caused by an FEC packet loss;

FIG. 26 illustrates an example of a transfer delay caused by an FEC packet loss; and

FIG. 27 illustrates an increase in the transfer delay caused in response to a retransmission.

### DESCRIPTION OF EMBODIMENTS

Some of the problems of related art are described below first, followed by the discussion of the embodiments.

As described below, related art techniques noted in a previous section suffer from a problem in which a transfer delay increases if data packets are transferred at a variable bit rate.

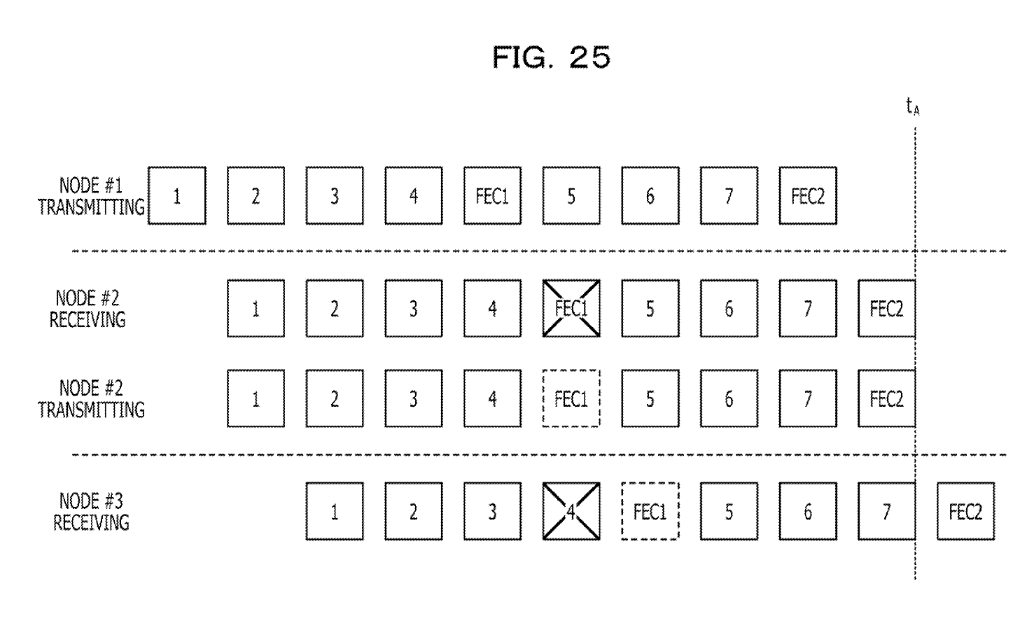

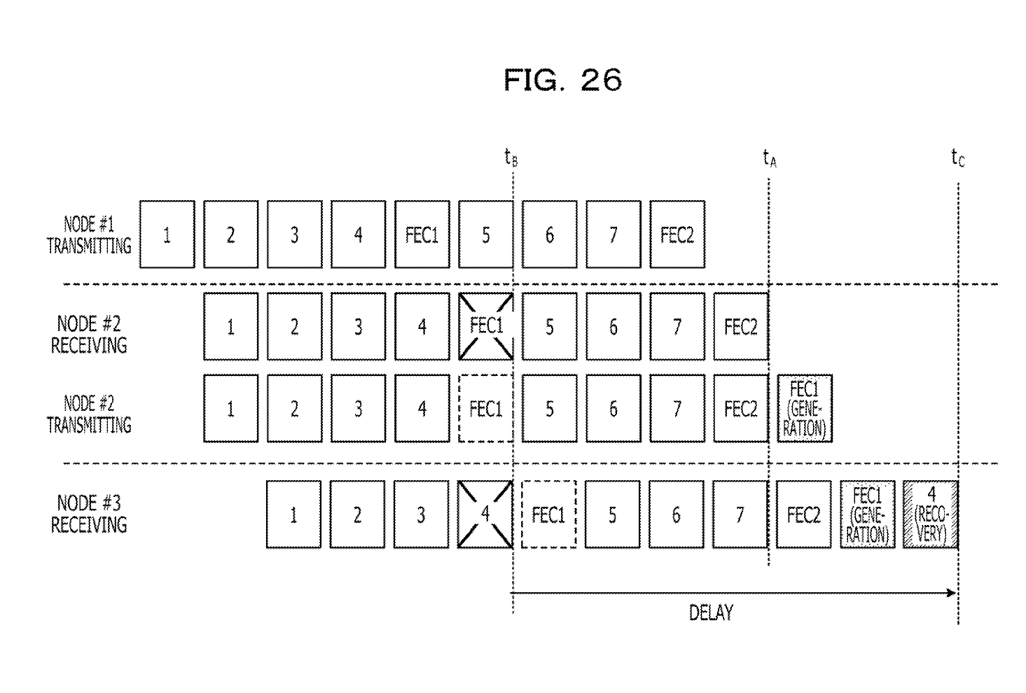

If an error correction packet is missing, a transfer delay of a data packet to be protected by the error correction packet is prolonged. FIGS. 25 and 26 illustrate an example of a transfer delay caused in response to a missing FEC packet. As illustrated in FIGS. 25 and 26, data transfer is performed in the order of a node #1, a node #2, and a node #3. FIGS. 25 and 26 illustrate sequence numbers attached to data packets, and sequence numbers attached to FEC packets, each packet denoted as a parcel. Data packets 1-4 may be protected through the error correction of an FEC packet 1, and data packets 5-7 may be protected through the error correction of an FEC packet 2. In FIGS. 25 and 26, the number of packets recovered by an FEC packet is one.

Referring to FIG. 25, the node #1 transfers to the node #2 the data packets 1-4, the FEC packet 1, the data packets 5-7, and the FEC packet 2 in that order. The FEC packet 1 may now be missing between the node #1 and the node #2. The node #2 receives from the node #1 the data packets 1-4, the data packets 5-7, and the FEC packet 2 in that order.

The node #2 is unable to detect that the FEC packet 1 has been missing until time T_{A} at the reception of the FEC packet 2. This is because the insertion intervals of the FEC packets are not constant but variable. No technique other than referencing protective coverage information included in the FEC packet 2 is available to detect a missing FEC packet 1. Since the node #2 is unable to detect at the reception of the data packets 1-4 that the FEC packet 1 has been missing, the node #2 transfers the packets to the node #3 with the FEC packet 1 missing.

If any data packet is missing from among the data packets 1-4 between the node #2 and the node #3, the node #3 is unable to recover the missing packet. Referring to FIG. 25, the node #3 is unable to recover a data packet 4 missing between the node #2 and the node #3. In such a case, the node #3 needs to cause the node #2 to retransmit the data packet 4 or the FEC packet 1.

Referring to FIG. 26, the node #2 detects for the first time the loss of the FEC packet 1 at time T_{A} at the reception of the FEC packet 2. The node #2 generates the FEC packet 1 using the data packets 1-4 already received, or causes the node #1 to retransmit the FEC packet 1. The node #2 thus acquires the FEC packet 1 and then transmits the FEC packet 1 to the node #3. On the other hand, the node #3 waits on standby until the FEC packet 1 has been received from the node #2, and then recovers the data packet 4 only after the FEC packet 1 is received from the node #2.

If the FEC packet 1 is missing in the node #2, and if the data packet 4 protected by the FEC packet 1 is missing at the lower-layer node #3, the transfer of the data packet 4 is delayed by a period from T_{B} to T_{C}, i.e., a time period equal to 7 packets.

The supportive use of a data transmitter apparatus is contemplated to detect the loss of an error correction packet quickly. An immediately preceding packet and a subsequent packet are transmitted, and a sequence number and a priority level of the immediately preceding packet are embedded in the subsequent packet. If such a data transmitter apparatus is in supportive use, it is contemplated that the sequence number of an FEC packet is embedded in a subsequent data packet before transmission. For example, Japanese Laid-open Patent Publication No. 2001-119437 (Apr. 27, 2001) discussed such a technique.

Even if such a data transmitter apparatus is in supportive use, a transfer delay may be increased in response to a subsequent retransmission of a data packet or an error correction packet.

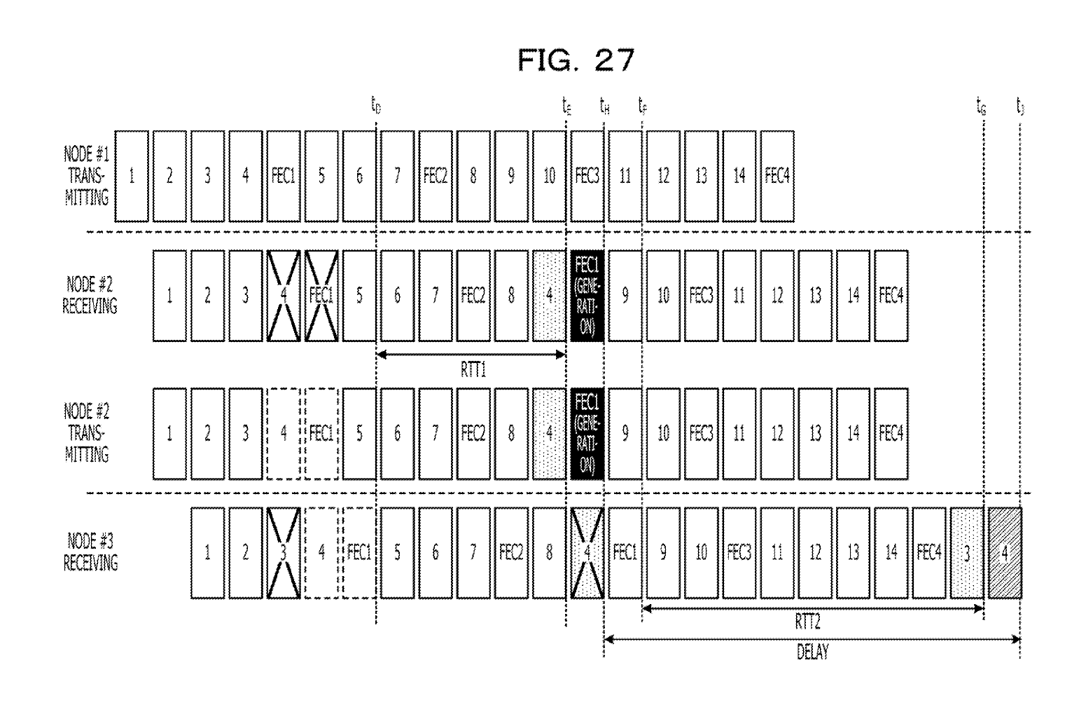

FIG. 27 illustrates an increase in the transfer delay caused in response to a retransmission. As illustrated in FIG. 27, a node #1, a node #2, and a node #3 are transferred in that order. As illustrated in FIG. 27, sequence numbers are respectively attached to packets, and sequence numbers are respectively attached to FEC packets, each packet denoted as a parcel. Data packets 1-4 are protected through the error correction of an FEC packet 1, and data packets 5-7 are protected through the error correction of an FEC packet 2. Data packets 8-10 are protected through the error correction of an FEC packet 3. Data packets 11-14 are protected through the error correction of an FEC packet 4. In FIG. 27, the number of packets recovered by an FEC packet is one.

If the data transmitter apparatus is in supportive use as illustrated in FIG. 27, the node #2 detects not only the loss of the data packet 4 but also the loss of the FEC packet 1 at time T_{D} at which the data packet 5 is received. Since the error correction is difficult with the FEC packet in this case, the node #2 transmits to the node #1 a retransmission request of the data packet 4 or the FEC packet 1 at time T_{D}. For example, if a retransmission request for the data packet 4 is placed, the node #2 receives a retransmitted data packet 4 at time T_{E} at which round trip time (RTT) equal to a round-trip delay time taken between the node #1 and the node #2 has elapsed. The node #2 then re-generates the FEC packet 1 using the data packet 4 retransmitted and received, and the data packets 1-3 received previously. The node #2 transmits to the node #3 the data packets 1-3, the data packets 5-7, the FEC packet 2, the data packet 8, the data packet 4, the FEC packet 1, . . . in that order.

The data packet 3 and the data packet 4 may now be missing between the node #2 and the node #3. At time T_{F} when the FEC packet 1 is received, the node #3 detects the loss of the data packet 3 and the data packet 4. In this case, the node #3 suffers from the loss of two packets, which is beyond the error correction capability of the FEC packet. The node #3 needs one of the data packet 3 and the data packet 4 retransmitted. For this reason, the node #3 transmits to the node #2 a retransmission request of one of the data packet 3 and the data packet 4 at time T_{F} when the FEC packet 1 is received.

If the retransmission request for the data packet 3 is placed, the node #3 receives a retransmitted data packet 3 at time T_{G} at which RTT2 equal to a round-trip delay time between the node #2 and the node #3 has elapsed. The node #3 recovers the data packet 4 using the data packet 3 retransmitted and received, and the data packets 1 and 2 and the FEC packet 1 previously received.

If a retransmission is repeated between different nodes, the transfer delay increases by RTT unit. As illustrated in FIG. 27, the transfer of the data packet 4 is delayed by a period from T_{H} to T_{J}, i.e., a period of 11 packets.

Example embodiments of a transfer apparatus and a transfer method are described with reference to the drawings. The embodiments are not limited to those described herein.

### First Embodiment

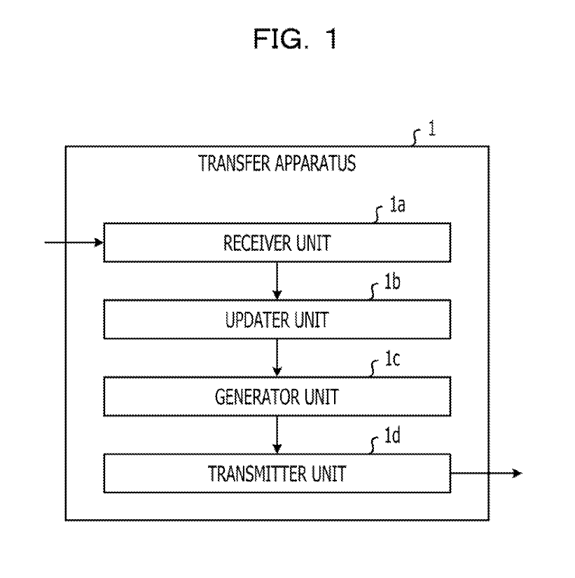

FIG. 1 is a block diagram illustrating a configuration of a transfer apparatus 1 of a first embodiment. The transfer apparatus 1 of FIG. 1 includes receiver unit (receiver) 1a, updater unit (updater) 1b, generator unit (generator) 1c, and transmitter unit (transmitter) 1d.

The receiver unit 1a receives one of a data packet and an error correction packet for correcting the data packet through an error correction process. The data packet includes protective coverage information written therein for identifying a protective coverage on the data packet that can be recovered through an error correction of the error correction packet.

The updater unit 1b updates the protective coverage information on the data packet in accordance with the order of reception of the data packet received by the receiver unit 1a. The generator unit 1c generates an error correction packet of the data packet identified by new protective coverage information when the protective coverage information is updated by the updater unit 1b. The transmitter unit 1d transmits the data packet responsive to the protective coverage information updated by the updater unit 1b and the error correction packet generated by the generator unit 1c.

The transfer apparatus 1 of the first embodiment changes the protective coverage of the error correction packet on the data packet in accordance with the order of reception of the data packet before transferring the data packet, and then generates a new error correction packet in accordance with the protective coverage and then transfers the new error correction packet.

The transfer apparatus 1 of the first embodiment re-generates the error correction packet at the end of the reception of the data packet regardless of the error correction packet loss unless the data packet protected by the error correction packet is retransmitted. The transfer apparatus 1 of the first embodiment reduces the possibility that the data transfer to a lower-layer apparatus continues with the error correction packet missing, and controls an increase in the transfer delay caused by the error correction packet loss. Even if the transfer order of some of the data packets protected by the same error correction packet changes in response to the retransmission, the transfer apparatus 1 of the first embodiment re-organizes the protective coverage such that the data packets close to each other in the transfer order to a lower-layer transfer apparatus are close to each other. Even if retransmission repeatedly occurs between different transfer apparatuses, the transfer apparatus 1 reduces the possibility of increase in the transfer delay. The transfer apparatus 1 of the first embodiment thus controls the transfer delay caused when the data packet is transferred at a variable bit rate.

### Second Embodiment

System Configuration

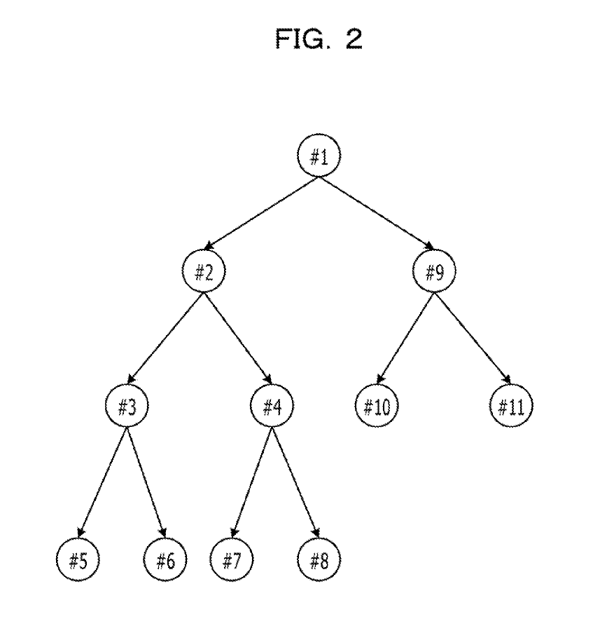

A transfer system of a second embodiment is described below. FIG. 2 illustrates a relay transfer executed by the transfer system of the second embodiment. As illustrated in FIG. 2, media data such as video or audio (sound) is transferred using the P2P system or the ALM system.

The transfer system of FIG. 2 includes transfer apparatuses called nodes arranged in a tree-like configuration. The transfer system performs a relay transfer to successively transfer data from a node #1 at a tree top to nodes at lower layers at a variable bit rate.

As illustrated in FIG. 2, the media data originated at the node #1 is relayed to node #5 and node #6 via node #2 and node #3. The data originated at the node #1 is also relayed to node #7 and node #8 via node #2 and node #4. The media data originated at the node #1 is relayed to node #10 and node #11 via node #9.

The transfer apparatuses at nodes #1-#11 may be information processing apparatuses having a communication function. For example, the transfer apparatuses may include fixed terminals such as a personal computer, or a server, or mobile terminals such as a cellular phones, a personal handy system (PHS), or a personal digital assistant (PDA), for example. The transfer apparatuses also include network devices such as a layer 3 switch (L3 switch), a router, or a computer having a routing function, for example. If the node #1 through the node #11 are described without discriminating one from another, these are simply referred to as the node hereafter.

RTP Header

Realtime transport protocol (RTP) may be used as a transfer method of the media data in the system of FIG. 2. Another transfer protocol, such as transport control protocol (TCP) or user datagram protocol (UDP), for example, may be used.

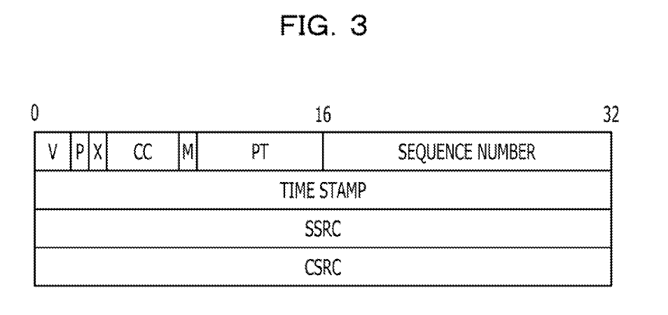

An RTP header attached the RTP packet to be transferred as the media data between the nodes of FIG. 2 is described below. FIG. 3 illustrates an example of the structure of the RTP header. A field labeled “V” refers to 2-bit data indicating a version in FIG. 3. A field labeled “P” refers to 1-bit data indicating a byte number padding a last portion of the RTP packet in FIG. 3. A field labeled “X” refers to a flag indicating whether the RTP packet is immediately followed by an extension header in FIG. 3. The extension header is not used here. A field labeled “CC” refers to 4-bit data indicating the number of contributing sources (CSRC) as a contributing transmission source identifier in FIG. 3.

A field labeled “M” refers to a marker bit indicating a boundary of application data in FIG. 3. The marker bit of the last data packet in one frame of a moving image is “1” in the media data compressed in accordance with moving picture experts group (MPEG) 4. A field labeled “PT” refers to 7-bit data indicating an encoding method of the application data in FIG. 3. A field labeled “Sequence Number” refers to 7-bit data indicating a sequence number of the RTP packet attached by a delivery source apparatus of the media data. A field labeled “Time Stamp” refers to 32-bit data indicating time at which a leading byte of the data packet is transmitted in FIG. 3. A field labeled “SSRC” (synchronization source) refers to a synchronization transmission source identifier identifying the delivery source of the media data. A field labeled “CSRC” refers to a contributing transmission source identifier indicating a host that has prepared the data packet, and the number of hosts is specified in the CC field.

FEC Packet

The node of FIG. 2 transfers a media data packet to a lower-layer node thereunder with a format error correction (FEC) packet attached to the media data packet. As long as the number of packet losses falls within the number of packets recoverable by the FEC packet, the node at the lower layer is free from requesting the node at the upper layer to retransmit the data packet. If the FEC packet is transferred in accordance with RFC2733, at least one FEC packet is attached to 24 RTP packet.

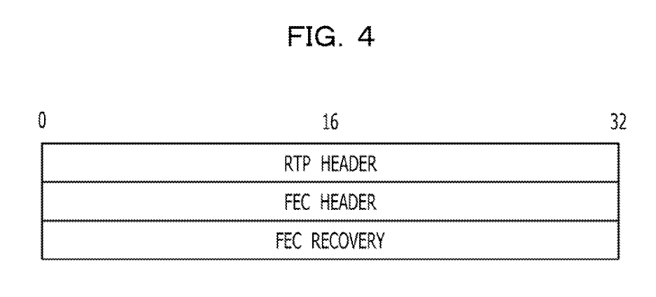

FIG. 4 illustrates an example of the structure of the FEC packet. As illustrated in FIG. 4, the FEC packet includes “FEC recovery” as parity information that is generated by exclusive OR gating RTP packets by bit unit, “FEC Header,” and “RTP header.”

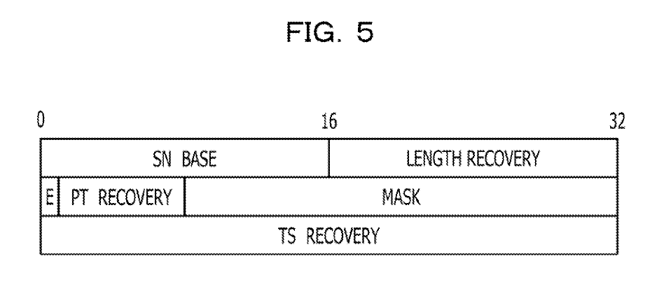

FIG. 5 illustrates an example of the structure of the FEC header. A field labeled “SN Base” refers to 16-bit data indicating an offset number of a sequence number of the RTP packet as a protective target of an FEC packet in FIG. 5. A field labeled “Length Recovery” refers to 16-bit data indicating parity information of the length of the RTP packet in FIG. 5. A field labeled “E” refers to a flag indicating whether the RTP header is extended or not in FIG. 5. A field labeled “PT Recovery” refers to 7-bit data indicating parity information of a PT bit of the RTP packet in FIG. 5. A field labeled “Mask” refers to a flag indicating an RTP packet as a protective target of the FEC packet in FIG. 5. The RTP packet as a protective target of the FEC packet is a (SN Base+i)-th data packet if i-th bit of Mask bits out of 24 packets from SN Base is “1.” A field labeled “TS Recovery” refers to 32-bit data indicating parity information of Time Stamp of the RTP packet in FIG. 5.

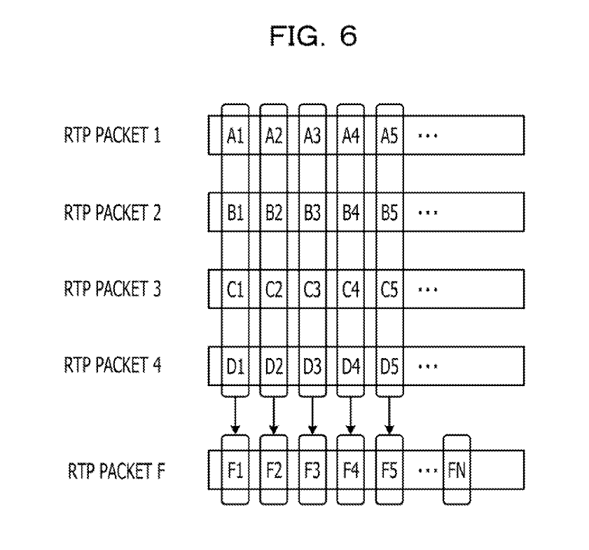

FIG. 6 illustrates a generation process of the parity information of the FEC packets. As illustrated in FIG. 6, the parity information is calculated by exclusive OR gating the RTP packets by bit unit. As illustrated in FIG. 6, bit F1 of the FEC packet F is calculated by summing a leading bit A1 of the RTP packet 1, a leading bit B1 of the RTP packet 2, a leading bit C1 of the RTP packet 3, and a leading bit D1 of the RTP packet 4. Bit F2 of the FEC packet F is calculated by summing a leading bit A2 of the RTP packet 1, a leading bit B2 of the RTP packet 2, a leading bit C2 of the RTP packet 3, and a leading bit D2 of the RTP packet 4. Similarly, bit F3 through Fn of the FEC packet F are calculated.

Configuration of the Transfer Apparatus

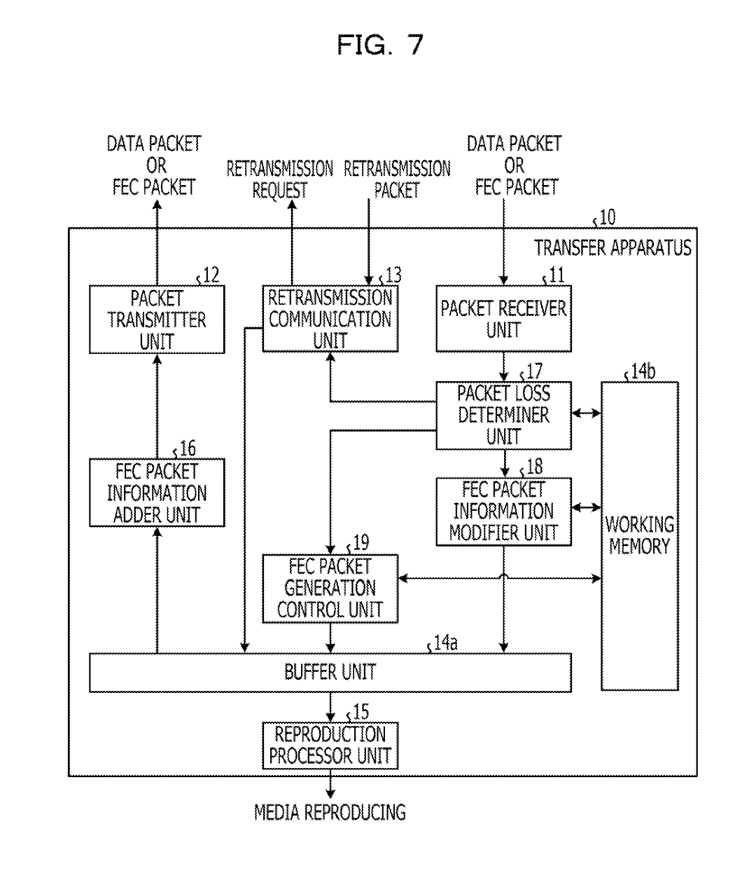

A transfer apparatus 10 of the second embodiment is described below. FIG. 7 is a block diagram of the configuration of the transfer apparatus 10 of the second embodiment. The transfer apparatus 10 includes a variety of function units of a known computer in addition to the function units illustrated in FIG. 7. For example, the transfer apparatus 10 includes a variety of input devices and a display device.

The transfer apparatus 10 of FIG. 7 includes packet receiver unit (packet receiver) 11, packet transmitter unit (packet transmitter) 12, retransmission communication unit 13, buffer unit (buffer) 14a, working memory (memory) 14b, and reproduction processor unit (processor) 15. The transfer apparatus 10 further includes FEC packet information adder unit (adder) 16, packet loss determiner unit (packet loss determiner) 17, FEC packet information modifier unit (modifier) 18, and FEC packet generation control unit (controller) 19. Not all nodes #1-#11 include the reproduction processor unit 15 of FIG. 7. It is also acceptable that the FEC packet information adder unit 16 of FIG. 7 is mounted on only the node #1 at the top layer.

The packet receiver unit 11 receives one of the data packet and the FEC packet transmitted from an upper-layer node.

The packet transmitter unit 12 transmits one of the data packet and the FEC packet to a lower-layer node. For example, the packet transmitter unit 12 transmits the data packet and the FEC packet, stored on the buffer unit 14a, at a variable bit rate (VBR) used in encoding. The packets may be transferred at the variable bit rate here. Optionally, the packets may be transferred at a constant bit rate (CBR).

The retransmission communication unit 13 performs communications related to a retransmission with an upper-layer node. In one operation example, the retransmission communication unit 13 places a retransmission request of the data packet to an upper-layer node in response to an instruction from the packet loss determiner unit 17 to be discussed later. In another operation example, the retransmission communication unit 13 receives a data packet transmitted from the upper-layer node.

The buffer unit 14a accumulates packets received by one of the packet receiver unit 11 and the retransmission communication unit 13. The buffer unit 14a is also used to absorb a transfer jitter between nodes. The working memory 14b is used by the packet loss determiner unit 17, the FEC packet information modifier unit 18, and the FEC packet generation control unit 19.

One example of each of the buffer unit 14a and the working memory 14b is a semiconductor memory such as a random-access memory (RAM), a read-only memory (ROM), or a flash memory. Optionally, the buffer unit 14a may include a storage device such as a hard disk or an optical disk, for example.

The reproduction processor unit 15 performs a reproduction process of the data packet stored on the buffer unit 14a. If MPEG is used as a compression-encoding method for the media data, the reproduction processor unit 15 functions as an MPEG decoder for decoding the data packet. The reproduction processor unit 15 reproduces decoded media data via a display and an audio output unit (both not illustrated). The compression-encoding method of the media data is not limited to MPEG. Another compression-encoding method may also be used.

The FEC packet information adder unit 16 adds the FEC packet information to a data packet into which the media data is packetized. The FEC packet information may include the protective coverage on the data packet recovered through the error correction of the FEC packet, the sequence number attached by the FEC packet, and an additional sequence number attached in the order of reception of the data packets, for example. The addition of the FEC packet information is not performed on the node #2 and the node #9 and lower-layer nodes as illustrated in FIG. 2.

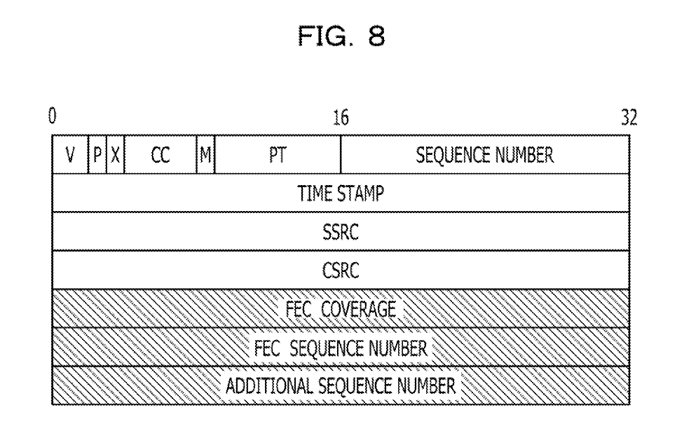

FIG. 8 illustrates an example of the FEC packet information added by the FEC packet information adder unit 16. As illustrated in FIG. 8, the FEC packet information is shadowed. The FEC packet information adder unit 16 adds, in succession to “CSRC” of the RTP packet, “FEC Coverage” as a protective coverage on the RTP packet provided by the FEC packet. The FEC packet information adder unit 16 also adds, in succession to “FEC coverage” on the RTP packet as a protective target, the sequence number of the FEC packet. The FEC packet information adder unit 16 also adds, in succession to “FEC Sequence Number” of the RTP packet as the protective target, the additional sequence number “Additional Sequence Number.”

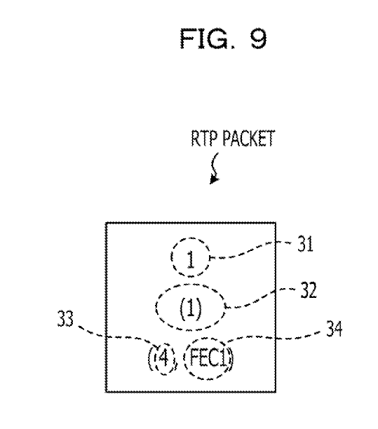

FIG. 9 illustrates an example of the FEC packet information included in the RTP packet. As illustrated in FIG. 9, the FEC packet information is encapsulated in the RTP packet denoted as a parcel. A sequence number 31 is attached to the data packet when the media data is packetized into the data packet. An additional sequence number 32 is attached to the data packet in each transfer apparatus in the order of reception. A protective coverage 33 indicates the protective coverage on the RTP packet protected by the FEC packet. A sequence number 34 is that of the FEC packet in FIG. 9.

With reference to FIG. 9, the sequence number of the RTP packet is “1,” and the additional sequence number of the RTP packet is “1.” The sequence number of the FEC packet protecting the RTP packet is “1.” The number of RTP packets to be protected by the FEC packet is “4.” In other words, the number of RTP packets refers to the number of packets on which the parity information is based.

Referring back to FIG. 7, the packet loss determiner unit 17 determines the packet loss of the data packet using the FEC packet information received by the packet receiver unit 11.

Each time one of the packet receiver unit 11 and the retransmission communication unit 13 receives a packet, the packet loss determiner unit 17 updates through an addition operation the number of receptions of the data packets stored on the working memory 14b. More specifically, the packet loss determiner unit 17 calculates a cumulative reception count of the data packets from the first reception of a packet to the current reception of a packet by referring to the working memory 14b. The packet loss determiner unit 17 thus determines the order of reception of the received packets.

A standard packet loss determination process is described below. The standard packet loss determination is performed if the packet receiver unit 11 receives a standard data packet rather than a retransmitted data packet. If a data packet is received, the packet loss determiner unit 17 determines whether the data packet is a first received packet. If the packet is a first received packet, the packet loss determiner unit 17 registers at the working memory 14b the FEC packet information including the additional sequence number, the protective coverage of the FEC packet, and the sequence number of the FEC packet. The packet loss determiner unit 17 makes a copy of the data packet and stores the copy onto the buffer unit 14a with the copy of the data packet different from the data packet to be transferred to a lower-layer node.

If the packet is not a first received packet, the packet loss determiner unit 17 determines whether the additional sequence number written in an RTP header of the currently received data packet and the additional sequence number of the immediately preceding received data packet are consecutive. In other words, the packet loss determiner unit 17 determines whether a difference between the additional sequence numbers of successively received data packets is 1. The presence or absence of a missing packet is determined by determining whether the additional sequence numbers are consecutive.

The packet loss determiner unit 17 references the FEC packet information stored on the working memory 14b and then determines whether the currently received data packet and the immediately preceding received data packet are identical to each other in terms of the protective coverage and the sequence number of the FEC packet. The packet loss determiner unit 17 performs this determination operation to determine whether the FEC packet information modifier unit 18 is to modify only the additional sequence number or to modify the FEC packet information together.

If the additional sequence numbers are consecutive, and if the protective coverage and the sequence number are identical to the respective counterparts thereof, the packet loss determiner unit 17 causes the FEC packet generation control unit 19 discussed below to XOR gate the currently received data packet. The packet loss determiner unit 17 then updates the additional sequence number stored on the working memory 14b to the additional sequence number of the currently received data packet. The packet loss determiner unit 17 determines whether the number of heretofore XOR gated data packets reaches the protective coverage of the FEC packet stored on the working memory 14b. If the number reaches the protective coverage of the FEC packet, the packet loss determiner unit 17 instructs the FEC packet generation control unit 19 to generate an FEC packet in accordance with the XOR gating results.

If the additional sequence numbers are consecutive, and if the protective coverage and the sequence number are not identical to the respective counterparts thereof, the packet loss determiner unit 17 makes a copy of the data packet to be used to generate a next FEC packet and then stores the copy on the buffer unit 14a. The packet loss determiner unit 17 registers on the working memory 14b the FEC packet information including the additional sequence number of the currently received data packet, the protective coverage of the FEC packet, and the sequence number of the FEC packet. The FEC packet information is registered to determine the packet loss related to a data packet protected by a next FEC packet subsequent to the FEC packet having protected the heretofore received data packets.

If the additional sequence numbers are not consecutive, and if the protective coverage and the sequence number are identical to the respective counterparts thereof, the packet loss determiner unit 17 performs a process described below. The packet loss determiner unit 17 determines whether the packet loss count has reached a value requiring retransmission within the protective coverage of the FEC packet written on the currently received data packet. For example, if the number of packets recoverable by the FEC packet is 1, the packet transmitter unit 12 determines whether the number of packet losses is 2 or larger. If the packet loss count has reached the value requiring retransmission within the protective coverage, the packet loss determiner unit 17 causes the retransmission communication unit 13 to transmit a retransmission request of missing data packets. The retransmission request requests the missing data packets to be transmitted starting with a data packet having the smallest additional sequence number. For example, the packet loss count may be 2. The packet loss determiner unit 17 leaves the packet count “1” recoverable by the FEC packet and causes the retransmission communication unit 13 to transmit a retransmission request of the other data packet. The packet loss determiner unit 17 then registers, in a retransmission waiting list stored on the working memory 14b, information related to the retransmission-requested data packet, for example, the sequence number of the data packet. The packet loss determiner unit 17 updates the additional sequence number stored on the working memory 14b to the additional sequence number of the currently received data packet.

If the additional sequence numbers are not consecutive, and if the protective coverage and the sequence number are not identical to the respective counterparts thereof, the packet loss determiner unit 17 performs a process described below. The packet loss determiner unit 17 determines whether the packet loss count has reached the value requiring retransmission within the protective coverage, immediately prior to the protective coverage of the FEC packet written on the currently received data packet, i.e., the protective coverage stored on the working memory 14b. If the packet loss count has reached the value requiring retransmission, the packet loss determiner unit 17 causes the retransmission communication unit 13 to transmit a retransmission request of missing data packets. The retransmission request requests the missing data packets to be transmitted starting with a data packet having the smallest additional sequence number. The packet loss determiner unit 17 then registers, in a retransmission waiting list stored on the working memory 14b, information related to the retransmission-requested data packet, for example, the sequence number of the data packet. The packet loss determiner unit 17 updates the FEC packet information stored on the working memory 14b to the additional sequence number of the currently received data packet, the protective coverage of the FEC packet, and the sequence number of the FEC packet.

Discussed below is the determination process of the packet loss performed if the packet receiver unit 11 receives the FEC packet. If the FEC packet is received, the packet loss determiner unit 17 acquires the sequence number of the data packet protected by the currently received FEC packet. The packet loss determiner unit 17 determines whether the sequence number of the previously received data packet is registered in a modification information list stored on the working memory 14b. The modification information list lists the sequence number of the data packet having the FEC packet information modified by the FEC packet information modifier unit 18 to be discussed later.

If the sequence number of the data packet is not registered in the modification information list, the packet loss determiner unit 17 searches the buffer unit 14a for the data packet corresponding to the sequence number of the data packet. If the sequence number of the data packet is registered in the modification information list, the packet loss determiner unit 17 searches the buffer unit 14a for the data packet corresponding to the sequence number of the data packet registered in the modification information list. In this case, the packet loss determiner unit 17 extracts the data packet prior to the modification of the FEC packet information and the data packet subsequent to the modification of the FEC packet information.

The packet loss determiner unit 17 determines whether the packet loss count has reached the value requiring retransmission within the protective coverage of the FEC packet written on the currently processed data packet. If the packet loss count has reached the value requiring retransmission, the packet loss determiner unit 17 causes the retransmission communication unit 13 to transmit a retransmission request of missing data packets. The retransmission request requests the missing data packets to be transmitted starting with a data packet having the smallest additional sequence number. The packet loss determiner unit 17 then registers, in the retransmission waiting list stored on the working memory 14b, information related to the retransmission-requested data packet, for example, the sequence number of the data packet.

If the packet loss count has not reached the value requiring retransmission, the packet loss determiner unit 17 further determines whether a packet loss is present within the protective coverage of the FEC packet written on the currently processed data packet. If a packet loss is present, the data packet may be recovered by the FEC packet. The packet loss determiner unit 17 thus causes the FEC packet generation control unit 19 discussed later to recover the data packet suffering from a packet loss in accordance with the currently received FEC packet. The packet loss determiner unit 17 then updates the FEC packet information stored on the working memory 14b to the additional sequence number of the currently recovered data packet, the protective coverage of the FEC packet, and the sequence number of the FEC packet.

The FEC packet information modifier unit 18 updates the FEC packet information on the data packet in accordance with the order of reception of the data packets received by the packet receiver unit 11 and the retransmission communication unit 13.

The packet receiver unit 11 may now receive a data packet, for example. If the packet loss determiner unit 17 detects a packet loss, the FEC packet information modifier unit 18 modifies the FEC packet information. An item of the FEC packet information to be modified is changed depending on whether a data packet and a subsequent data packet are identical in terms of the protective coverage and the sequence number of the FEC packet.

If the protective coverage and the sequence number are identical to the respective counterparts thereof, the FEC packet information modifier unit 18 modifies the additional sequence number of the FEC packet information written on the RTP header of the received data packet. More specifically, the FEC packet information modifier unit 18 writes the number of receptions stored on the working memory 14b, i.e., the order of reception of the data packet, onto a region of the additional sequence number assigned in the RTP header of the currently received data packet. The FEC packet information modifier unit 18 then registers the sequence number attached to the currently received data packet in the modification information list on the working memory 14b.

If the FEC packets are not identical in terms of the protective coverage and the sequence number, the FEC packet information modifier unit 18 performs a process described below. The FEC packet information modifier unit 18 modifies the additional sequence number written on the RTP header of the received data packet, and the protective coverage of the FEC packet and the sequence number of the FEC packet. The FEC packet information modifier unit 18 further registers the sequence number attached to the currently received data packet in the modification information list on the working memory 14b.

In order to modify all the FEC packet information, the FEC packet information modifier unit 18 writes the order of reception of the currently received data packet onto a region of the additional sequence number assigned to the RTP header. The FEC packet information modifier unit 18 further writes the protective coverage of the FEC packet and the sequence number of the FEC packet stored on the working memory 14b onto the RTP header.

If the FEC packet generation control unit 19 discussed later has recovered data packets, the FEC packet information modifier unit 18 modifies all the FEC packet information of the recovered data packets in another operation example. The FEC packet information modifier unit 18 then registers the sequence number attached to the currently received data packet in the modification information list on the working memory 14b.

If the retransmission communication unit 13 has received a retransmitted data packet, the FEC packet information modifier unit 18 modifies all the FEC packet information of the retransmitted packet in another operation example. The FEC packet information modifier unit 18 then registers the sequence number attached to the currently received data packet in the modification information list on the working memory 14b.

The FEC packet generation control unit 19 controls the generation of the FEC packet. In one operation example, the FEC packet generation control unit 19 XOR gates the data packet received by the packet receiver unit 11 and the data packet retransmitted and then received by the retransmission communication unit 13, in response to an instruction from the packet loss determiner unit 17. If the number of data packets having undergone the XOR gating operation reaches the protective coverage of the FEC packet stored on the working memory 14b, the FEC packet generation control unit 19 generates an FEC packet from the results of the XOR gating of the data packets. In yet another operation, the FEC packet generation control unit 19 recovers the data packet suffering from the packet loss within the protective coverage of the FEC packet using the FEC packet received by the packet receiver unit 11.

A variety of integrated circuits or electronic circuits may be employed as the packet receiver unit 11, the packet transmitter unit 12, the retransmission communication unit 13, the reproduction processor unit 15, the FEC packet information adder unit 16, the packet loss determiner unit 17, the FEC packet information modifier unit 18, and the FEC packet generation control unit 19. The integrated circuit may include an application specific integrated circuit (ASIC), for example. The electronic circuit may include a central processing unit (CPU), or a micro processing unit (MPU), for example.

Process Flow

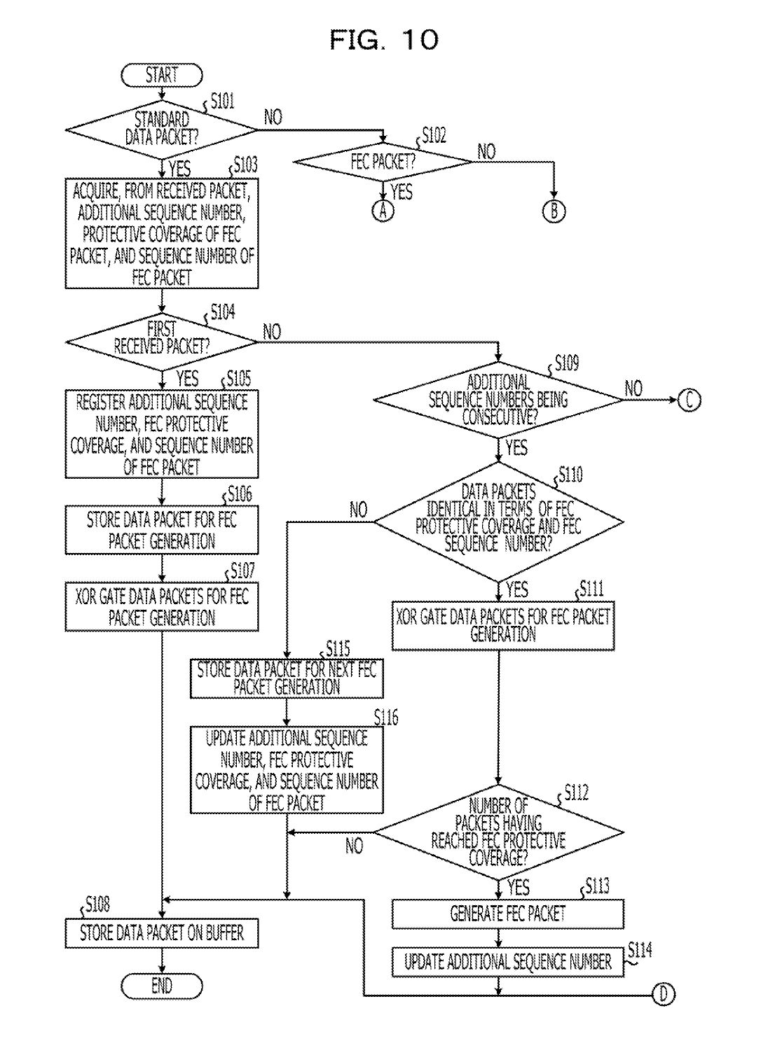

A process flow of the transfer apparatus of the embodiment is described below. FIGS. 10-13 are a flowchart of a packet reception process of the second embodiment. The packet reception process is initiated when one of the packet receiver unit 11 and the retransmission communication unit 13 receives a packet.

Upon receiving a packet from an upper-layer node as illustrated in FIG. 10, the packet loss determiner unit 17 determines whether the received packet is a standard data packet (S101).

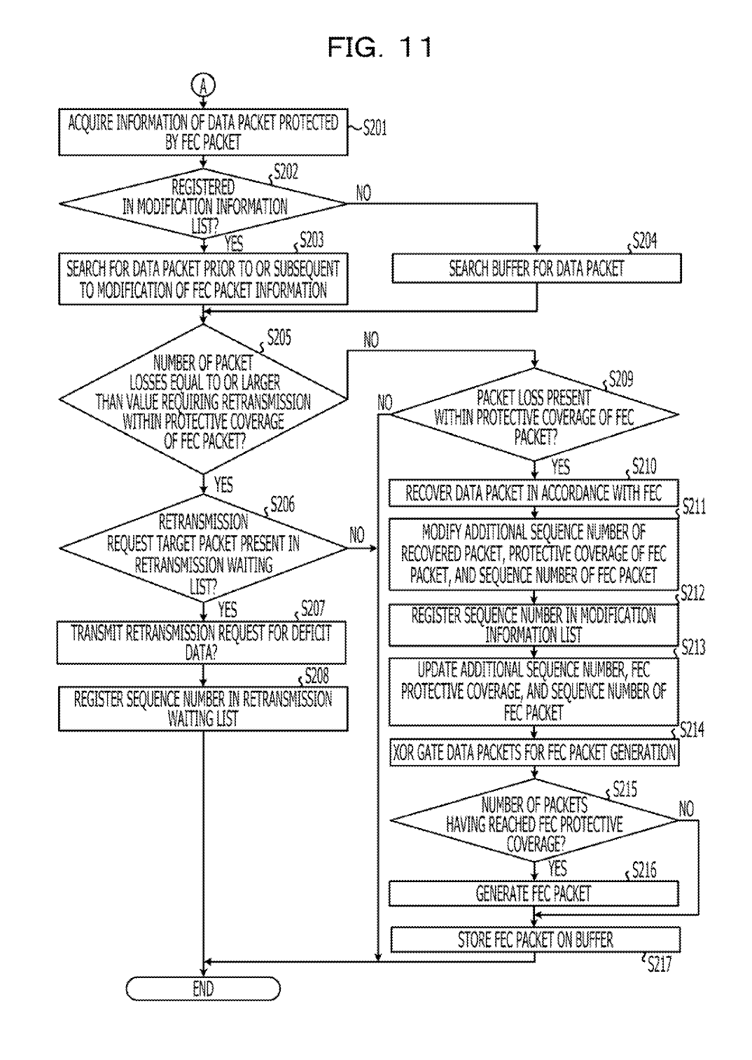

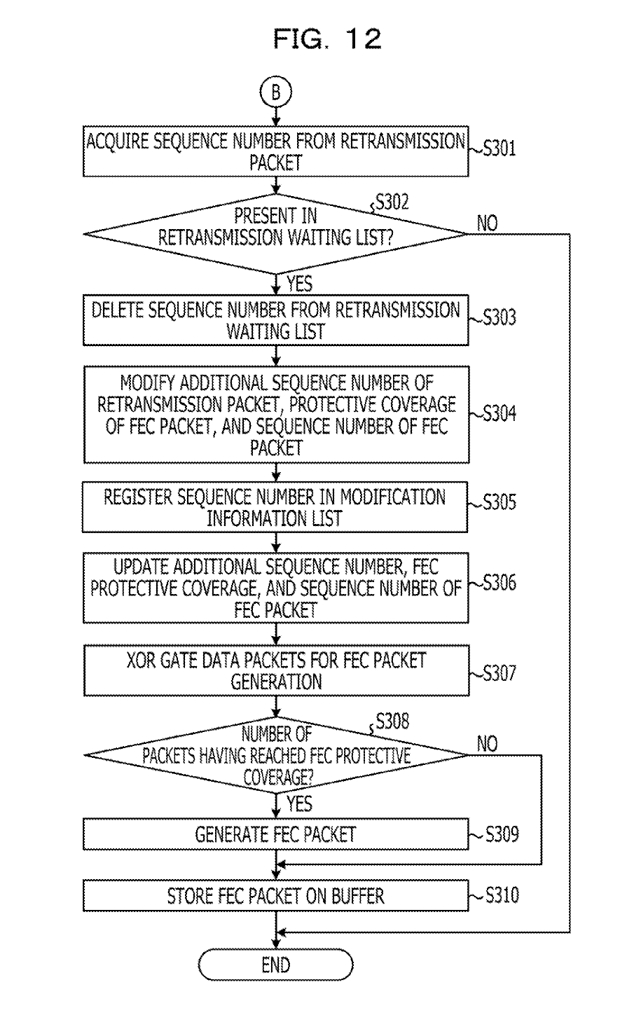

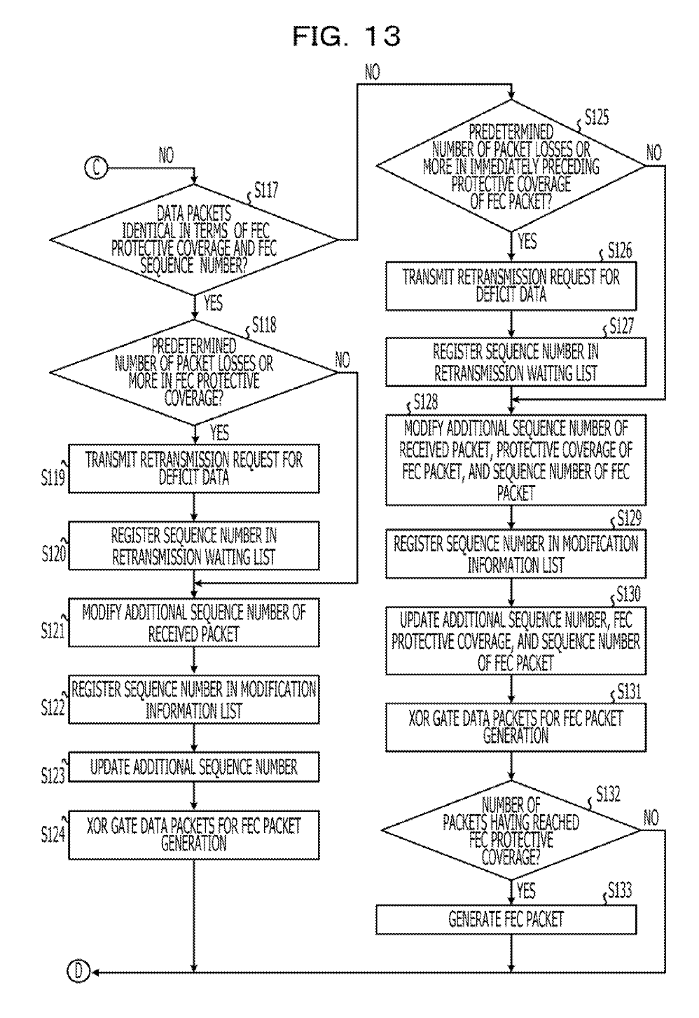

If the received packet is a standard data packet (yes from S101), the data packet reception process from S103 to S133 of FIGS. 10 and 13 is performed. If the received packet is not a standard data packet but an FEC packet (no from S101 and yes from S102), an FEC packet reception process from S201 to S217 of FIG. 11 is performed. If the received packet is neither a standard data packet nor an FEC packet, but is a retransmitted packet (no from S101 and no from S102), a retransmission packet reception process from S301 to S310 of FIG. 12 is performed.

The data packet reception process is discussed. If the received packet is a standard data packet (yes from S101), the packet loss determiner unit 17 acquires the FEC packet information written on the RTP header of the data packet (S103). For example, the packet loss determiner unit 17 acquires, as the FEC packet information, the additional sequence number, the protective coverage of the FEC packet, and the sequence number of the FEC packet.

The packet loss determiner unit 17 determines whether the data packet is a first received packet (S104). If the data packet is a first received packet (yes from S104), the packet loss determiner unit 17 performs a process described below. The packet loss determiner unit 17 registers on the working memory 14b the FEC packet information including the additional sequence number, the protective coverage of the FEC packet, and the sequence number of the FEC packet (S105).

The packet loss determiner unit 17 makes a copy of the data packet to generate an FEC packet, separately from the data packet to be transferred to a lower-layer node, and then stores the copy of the data packet on the buffer unit 14a (S106). The FEC packet generation control unit 19 XOR gates the currently received data packet (S107). The FEC packet generation control unit 19 stores on the buffer unit 14a the currently received data packet as a data packet to be transferred (S108), and ends the process.

If the data packet is not a first received packet (no from S104), the packet loss determiner unit 17 performs a process described below. The packet loss determiner unit 17 determines whether the additional sequence number written on the RTP header of the currently received data packet and the additional sequence number of the immediately preceding received data packet are consecutive (S109).

The packet loss determiner unit 17 further determines whether the currently received data packet and the immediately preceding received data packet are identical in terms of the protective coverage of the FEC packet and the sequence number of the FEC packet (S110 and S117).

If the additional sequence numbers are consecutive, and if the data packets are identical in terms of the protective coverage of the FEC packet and the sequence number of the FEC packet (yes from S110 or yes from S117), the FEC packet generation control unit 19 performs a process described below. The FEC packet generation control unit 19 XOR gates the currently received data packet (S111).

The FEC packet generation control unit 19 determines whether the number of data packets having undergone the XOR gating reaches the protective coverage of the FEC packet stored on the working memory 14b (S112). If the number of data packets having undergone the XOR gating does not reach the protective coverage of the FEC packet (no from S112), the FEC packet generation control unit 19 stores on the buffer 14a the currently generated FEC packets together with the data packets received by the packet receiver unit 11, and ends the processing. If the number of data packets having undergone the XOR gating reaches the protective coverage of the FEC packet (yes from S112), the FEC packet generation control unit 19 generates an FEC packet from the data packets heretofore XOR gated (S113).

The packet loss determiner unit 17 updates the additional sequence number stored on the working memory 14b to the additional sequence number of the currently received data packet (S114). The FEC packet generation control unit 19 stores on the buffer unit 14a the generated FEC packet together with the data packet currently received by the packet receiver unit 11 (S108). Processing thus ends.

If the additional sequence numbers are consecutive, and if the data packets are not identical in terms of the protective coverage of the FEC packet and the sequence number of the FEC packet (yes from S109 and no from S110), the packet loss determiner unit 17 performs a process described below. The packet loss determiner unit 17 makes a copy of the data packet to be used to generate a next FEC packet and then stores the copy on the buffer unit 14a (S115).

The packet loss determiner unit 17 updates on the working memory 14b the FEC packet information including the additional sequence number of the currently received data packet, the protective coverage of the FEC packet, and the sequence number of the FEC packet (S116). The FEC packet generation control unit 19 stores on the buffer unit 14a the currently received data packet as a transfer data packet (S108).

If the additional sequence numbers are not consecutive, and if the data packets are identical in terms of the protective coverage of the FEC packet and the sequence number of the FEC packet (no from S109 and yes from S117), data packet reception processing from operations S117 to S133 illustrated in FIG. 13 is performed.

The packet loss determiner unit 17 performs a process described below. The packet loss determiner unit 17 determines whether the packet loss count has reached a value requiring retransmission within the protective coverage of the FEC packet written on the currently received data packet (S118). If the packet loss count has not reached the value requiring retransmission (no from S118), processing proceeds to S121.

If the packet loss count has reached the value requiring retransmission (yes from S118), the packet loss determiner unit 17 performs a process described below. The packet loss determiner unit 17 causes the retransmission communication unit 13 to transmit a retransmission request for missing data packets (S119). The retransmission request requests the missing data packets to be transmitted starting with a data packet having the smallest additional sequence number. The packet loss determiner unit 17 then registers, in a retransmission waiting list stored on the working memory 14b, information related to the retransmission-requested data packet, for example, the sequence number of the data packet (S120).

The FEC packet information modifier unit 18 modifies the additional sequence number of the FEC packet information written on the RTP header of the received data packet (S121). The FEC packet information modifier unit 18 registers the sequence number assigned to the currently received data packet in the modification information list on the working memory 14b (S122).

The packet loss determiner unit 17 updates the additional sequence number stored on the working memory 14b to the additional sequence number of the currently received data packet (S123). The FEC packet generation control unit 19 XOR gates the currently received data packet (S124). The FEC packet generation control unit 19 stores the data packet received by the packet receiver unit 11 on the buffer unit 14a (S108), and ends the process.

If the additional sequence numbers are not consecutive, and if the protective coverage and the sequence numbers are not identical to their counterparts (no from S109 and no from S117), the packet loss determiner unit 17 performs a process described below. The packet loss determiner unit 17 determines whether the packet loss count has reached the value requiring retransmission within the protective coverage, immediately prior to the protective coverage of the FEC packet written on the currently received data packet (S125). If the packet loss count has not reached the value requiring retransmission (no from S125), processing proceeds to S128.

If the packet loss count has reached the value requiring retransmission (yes from S125), the packet loss determiner unit 17 performs a process described below. The packet loss determiner unit 17 causes the retransmission communication unit 13 to transmit a retransmission request for missing data packets (S126). The retransmission request requests the missing data packets to be transmitted starting with a data packet having the smallest additional sequence number. The packet loss determiner unit 17 then registers, in the retransmission waiting list stored on the working memory 14b, information related to the retransmission-requested data packet, for example, the sequence number of the data packet (S127).

The FEC packet information modifier unit 18 modifies the additional sequence number, the protective coverage of the FEC packet, and the sequence number of the FEC packet written on the RTP header of the received data packet (S128). The FEC packet information modifier unit 18 registers the sequence number assigned to the currently received data packet in the modification information list on the working memory 14b (S129).

The packet loss determiner unit 17 updates the FEC packet information stored on the working memory 14b to the additional sequence number of the currently received data packet, the protective coverage of the FEC packet, and the sequence number of the FEC packet (S130).

The FEC packet generation control unit 19 XOR gates the currently received data packet (S131). The FEC packet generation control unit 19 determines whether the number of XOR gated data packets has reached the protective coverage of the FEC packet stored on the working memory 14b (S132).

If the number of XOR gated data packets has reached the protective coverage of the FEC packet (yes from S132), the FEC packet generation control unit 19 generates an FEC packet from the data packets heretofore XOR gated (S133). The FEC packet generation control unit 19 stores, on the buffer unit 14a, the currently generated FEC packet together with the data packet received by the packet receiver unit 11 (S108). Processing thus ends.

If the number of XOR gated data packets has not reached the protective coverage of the FEC packet (no from S132), the FEC packet generation control unit 19 stores the data packet received by the packet receiver unit 11 on the buffer unit 14a (S108), and processing ends.

The FEC packet reception process is discussed further with reference to FIG. 11. If an FEC packet has been received (yes from S102), the packet loss determiner unit 17 acquires the sequence number of the data packet protected by the currently received FEC packet (S201).

The packet loss determiner unit 17 determines whether the sequence number of the previously received data packet is listed in the modification information list stored on the working memory 14b (S202).

If the sequence number of the previously received data packet is listed in the modification information list (yes from S202), the packet loss determiner unit 17 performs a process described below. The packet loss determiner unit 17 searches the buffer unit 14a for the data packet having the unmodified FEC packet information and the data packet having the modified FEC packet information (S203).

If the sequence number of the previously received data packet is not listed in the modification information list stored on the working memory 14b (no from S202), the packet loss determiner unit 17 searches the buffer unit 14a for the data packet corresponding to the sequence number (S204).

The packet loss determiner unit 17 determines whether the packet loss count has reached a value requiring retransmission within the protective coverage of the FEC packet written on the currently hit data packet (S205).

If the packet loss count has reached the value requiring retransmission (yes from S205), the packet loss determiner unit 17 performs a process described below. The packet loss determiner unit 17 determines whether the lost data packet, i.e., the packet as a retransmission request target, is registered in a retransmission waiting list stored on the working memory 14b (S206). If the lost packet data is not registered in the retransmission waiting list (no from S206), processing ends.

If the lost packet data is registered in the retransmission waiting list (yes from S206), the packet loss determiner unit 17 performs a process described below. The packet loss determiner unit 17 causes the retransmission communication unit 13 to transmit a retransmission request for missing data packets (S207). The retransmission request requests the missing data packets to be transmitted starting with a data packet having the smallest additional sequence number. The packet loss determiner unit 17 then registers, in the retransmission waiting list stored on the working memory 14b, information related to the retransmission-requested data packet, for example, the sequence number of the data packet (S208). Processing thus ends.

If the packet loss count has not reached the value requiring retransmission (no from S205), the packet loss determiner unit 17 performs a process described below. The packet loss determiner unit 17 determines whether any packet loss is present in the protective coverage of the FEC packet written on the currently hit data packet (S209).

If no packet loss is present (no from S209), processing ends. If a packet loss is present (yes from S209), the FEC packet generation control unit 19 recovers the lost data packet using the currently received FEC packet (S210).

The FEC packet information modifier unit 18 modifies the additional sequence number, the protective coverage of the FEC packet, and the sequence number of the FEC packet written on the RTP header of the recovered data packet (S211). The FEC packet information modifier unit 18 registers the sequence number assigned to the recovered data packet in the modification information list on the working memory 14b (S212).

The packet loss determiner unit 17 updates the FEC packet information stored on the working memory 14b to the additional sequence number of the currently recovered data packet, the protective coverage of the FEC packet, and the sequence number of the FEC packet (S213).

The FEC packet generation control unit 19 XOR gates the recovered data packet (S214). The FEC packet generation control unit 19 determines whether the number of XOR gated data packets has reached the protective coverage of the FEC packet stored on the working memory 14b (S215).

If the number of XOR gated data packets has reached the protective coverage of the FEC packet (yes from S215), the FEC packet generation control unit 19 generates an FEC packet from the data packets heretofore XOR gated (S216). The FEC packet generation control unit 19 stores, on the buffer unit 14a, the currently generated FEC packet together with the currently recovered data packet (S217). Processing thus ends.

If the number of XOR gated data packets has not reached the protective coverage of the FEC packet (no from S215), the FEC packet generation control unit 19 stores the currently recovered data packet on the buffer unit 14a (S217). Processing ends.

The retransmission packet reception process is described below with reference to FIG. 12. If a retransmission data packet is received (no from S102), the packet loss determiner unit 17 acquires the sequence number of the data packet written on the RTP header of the retransmission data packet (S301).

The packet loss determiner unit 17 determines whether the sequence number of the retransmission data packet is present (registered) in the retransmission waiting list on the working memory 14b (S302). If the sequence number is not registered in the retransmission waiting list (no from S302), processing ends.

If the sequence number is registered in the retransmission waiting list (yes from S302), the packet loss determiner unit 17 deletes the sequence number of the retransmission data packet from the retransmission waiting list (S303).

The FEC packet information modifier unit 18 modifies the additional sequence number, the protective coverage of the FEC packet, and the sequence number of the FEC packet written on the RTP header of the retransmitted data packet (S304). The FEC packet information modifier unit 18 registers the sequence number assigned to the retransmitted data packet in the modification information list on the working memory 14b (S305).

The packet loss determiner unit 17 updates the FEC packet information stored on the working memory 14b to the additional sequence number of the currently retransmitted data packet, the protective coverage of the FEC packet, and the sequence number of the FEC packet (S306).

The FEC packet generation control unit 19 XOR gates the retransmitted data packet (S307). The FEC packet generation control unit 19 determines whether the number of XOR gated data packets has reached the protective coverage of the FEC packet stored on the working memory 14b (S308).

If the number of XOR gated data packets has reached the protective coverage of the FEC packet (yes from S308), the FEC packet generation control unit 19 generates an FEC packet from the data packets heretofore XOR gated (S309). The FEC packet generation control unit 19 stores, on the buffer unit 14a, the currently generated FEC packet together with the currently retransmitted data packet (S310). Processing thus ends.

If the number of XOR gated data packets has not reached the protective coverage of the FEC packet (no from S308), the FEC packet generation control unit 19 stores the currently retransmitted data packet on the buffer unit 14a (S310). Processing thus ends.

Advantages of the Second Embodiment

As described above, the transfer apparatus 10 of the second embodiment re-generates the error correction packet at the end of the reception of the data packet regardless of the error correction packet loss unless the data packet protected by the error correction packet is retransmitted. The transfer apparatus 10 of the second embodiment reduces the possibility that the data transfer to a lower-layer apparatus continues with the missing error correction packet unnoticed, and controls an increase in the transfer delay caused by the error correction packet loss. Even if the transfer order of some of the data packets protected by the same error correction packet changes in response to the retransmission, the transfer apparatus 10 of the second embodiment re-organizes the protective coverage such that the data packets close to each other in the transfer order to a lower-layer transfer apparatus are organized close to each other. Even if retransmission repeatedly occurs between different transfer apparatuses, the transfer apparatus 10 reduces the possibility of increase in the transfer delay. The transfer apparatus 10 of the second embodiment thus controls the transfer delay caused when the data packet is transferred at a variable bit rate.

When the data packet is received, the transfer apparatus 10 of the second embodiment determines the packet loss of the data packet using the additional sequence number included in the data packet. In response to the packet loss determination results, the transfer apparatus 10 of the second embodiment places the retransmission request of the data packet to an upper-layer node, and then receives a retransmitted data packet. The transfer apparatus 10 of the second embodiment updates the FEC packet information of the data packets in the order of reception of the data packets including the data packet retransmitted and then received. The transfer apparatus 10 of the second embodiment detects the presence or absence of the packet loss each time the data packet is received. The transfer apparatus 10 of the second embodiment controls the transfer delay caused with the data packet transferred at a variable bit rate while reducing the waiting time of the data packet.

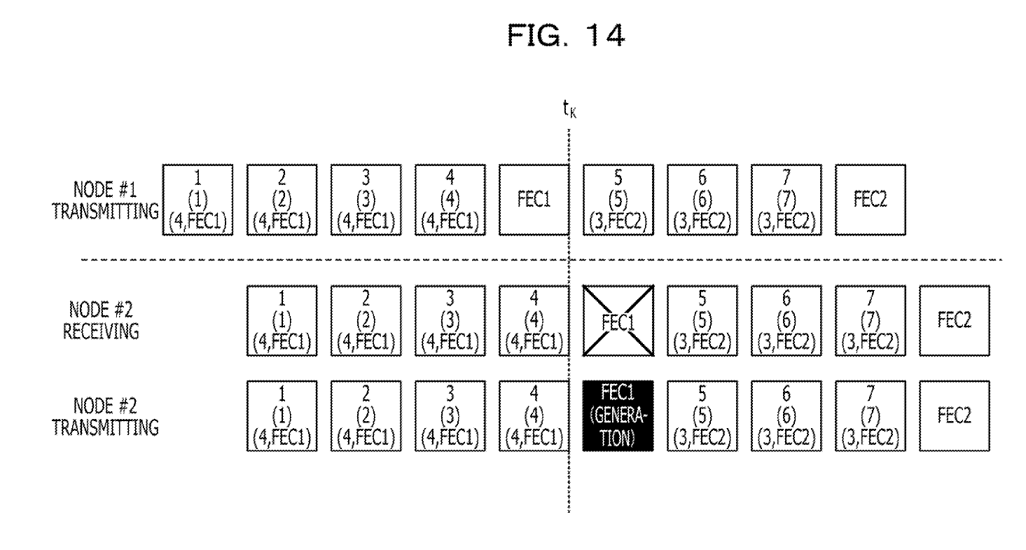

Those advantages are described with reference a transfer example. FIG. 14 illustrates an example of a data transfer process by the transfer apparatus of the second embodiment. As illustrated in FIG. 14, data is transferred from a node #1 to a node #2. FIG. 14 illustrates sequence numbers, and additional sequence numbers assigned to data packets, and protective coverage, and sequence numbers assigned to the FEC packets, each packet diagrammatically denoted by a parcel. Data packets 1-4 are protected through the error correction of an FEC packet 1, and data packets 5-7 are protected through the error correction of an FEC packet 2. In FIG. 14, the number of packets recovered by an FEC packet is one.

Referring to FIG. 14, the FEC packet information adder unit 16 of the node #1 assigns additional sequence numbers to data packets with the sequence number incremented on each of the data packets in the order of transmission. The FEC packet information adder unit 16 of the node #1 also attaches the protective coverage of the FEC packet to the data packet. For example, an FEC packet 1 is constructed of the data packets 1-4, and the packet number of “4” protected by the FEC packet 1 is attached to the FEC packet 1 as a protective coverage of the FEC packet for the data packets 1-4. The FEC packet information adder unit 16 of the node #1 also attaches to each data packet the sequence number assigned to the FEC packet. The FEC packet information adder unit 16 in each of the node #2 and subsequent nodes does not add the FEC packet information because the FEC packet information is already added.

The protective coverage of the FEC packet (4, 3, . . . ) is added to the field “FEC Coverage” of FIG. 10 when the FEC packet information is added. The fields “SN Base” and “Mask” of the RTP header of the FEC packet of FIG. 8 are set in accordance with the additional sequence number. For example, set for the FEC packet 1 is “SN Base:1, Mask: 0xF00000.” In this case, upper 4 bits are a protective target. The fields “SN Base” and “Mask” are set in accordance with the additional sequence number. Alternatively, the fields “SN Base” and “Mask” may be set in accordance with the sequence number of the data packet.

As illustrated in FIG. 14, the node #1 transfers to the node #2 the data packets 1-4, the FEC packet 1, the data packets 5-7, and the FEC packet 2 in that order. The FEC packet 1 may be assumed to be lost between the node #1 and the node #2. In this case, the node #2 receives from the node #1 the data packets 1-4, the data packets 5-7, and the FEC packet 2 in that order.

The node #2 XOR gates the data packets each time each of the data packets 1-4 is received. At time T_{K} the protective coverage “4” of the FEC packet is reached, the calculation of the parity information of the FEC packet 1 is complete. Regardless of whether the FEC packet 1 is lost between the node #1 and the node #2, the node #2 can re-generate an FEC packet 1 and transmit the FEC packet 1 to a lower-layer node. The FEC packet 1 is transferred to a lower-layer node without the need for detecting the loss of the FEC packet 1. The second embodiment thus reduces the possibility that the data transfer continues to a lower-layer node with the FEC packet 1 remaining missing, and thus controls an increase in the transfer delay due to the loss of the FEC packet.

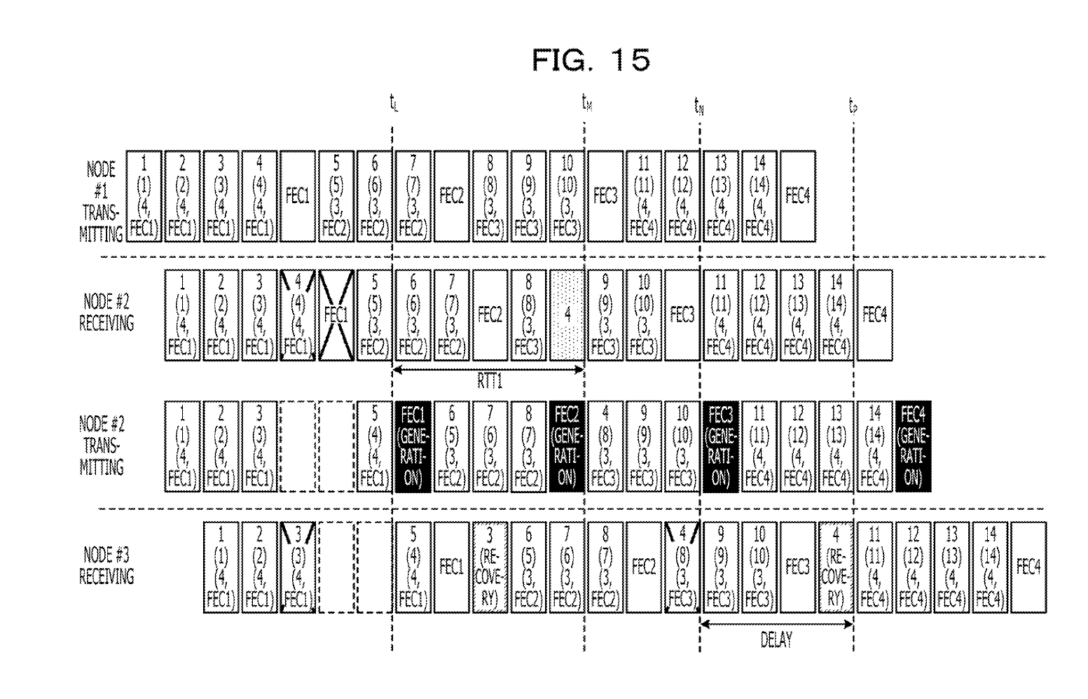

FIG. 15 illustrates an example of the data transfer of the transfer apparatus of the second embodiment. As illustrated in FIG. 15, a node #1, a node #2, and a node #3 perform the data transfer in that order. FIG. 15 illustrates sequence numbers and additional sequence numbers assigned to data packets, and, protective coverage, and sequence numbers assigned to the FEC packets, each packet diagrammatically denoted by a parcel. Data packets 1-4 are protected through the error correction of an FEC packet 1, data packets 5-7 are protected through the error correction of an FEC packet 2, and data packets 8-10 are protected through the error correction of an FEC packet 3. Data packets 11-14 are protected through the error correction of an FEC packet 4. In FIG. 15, the number of packets recovered by an FEC packet is one.

Referring to FIG. 15, at time T_{L} at which the data packet 5 is received, the node #2 detects the loss of the data packet 4 because the additional sequence number “5” is not consecutive with the additional sequence number “3” of the previously received data packet 3. The node #2 detects the loss of the FEC packet 1 because the protective coverage of the FEC packet for the currently received data packet 5 is different from the sequence number of the FEC packet. Since the packet loss exceeds the error correction capability of the FEC packet, the node #2 transmits to the node #1 a retransmission request of the data packet 4 at time T_{L}. The retransmission-requested data packet 4 reaches the node #2 at time T_{M} at which round trip time (RTT) 1 between the node #1 and the node #2 has elapsed.

The node #2 operates in a manner different from the related art technique as illustrated in FIG. 27 in which the FEC packet 1 is generated by XOR gating the data packets 1-4 in response to the reception of the retransmitted data packet 4.

More specifically, the node #2 modifies the FEC packet information of the data packet 5. The node #2 rewrites the additional sequence number “5” of the data packet 5 to the order of reception “4” in the node #2. The node #2 further rewrites the protective coverage “3” of the FEC packet for the data packet 5 to the protective coverage “4” of the FEC packet stored on the working memory 14b. The node #2 rewrites the sequence number “2” of the FEC packet for the data packet 5 to the sequence number “1” of the FEC packet stored on the working memory 14b.

The node #2 then re-generates the FEC packet 1 in accordance with the data packet 1, the data packet 2, the data packet 3, and the data packet 5. At time T_{L} at which the data packet 5 is received, the data packet 1 through the data packet 3 are already XOR gated. The XOR gated results are XOR gated with the data packet 5, and the FEC packet 1 is thus generated.

As the FEC packet information of the data packet 5 is modified, the node #2 updates the data packet 6 through the data packet 8 that are to arrive by the reception of the retransmitted data packet 4, i.e., increments the additional sequence numbers of the data packet 6 through the data packet 8 by one. The data packets 6-8 are XOR gated at the moment the data packet 8 is received. The protective coverage “3” of the FEC packet that is registered on the working memory 14b at the reception of the data packet 6 is thus satisfied. The node #2 causes the protective coverage “3” of the FEC packet for the data packet 8 to overwrite the protective coverage “3” of the FEC packet stored on the working memory 14b. The node #2 rewrites the sequence number “3” of the FEC packet for the data packet 8 to the sequence number “2” of the FEC packet stored on the working memory 14b. The node #2 then re-generates the FEC packet 2 using the XOR gating results of the data packets 6-8.

Upon receiving the retransmitted data packet 4, the node #2 rewrites the additional sequence number “4” of the data packet 4 as the order of reception “8” in the node #2. The node #2 further rewrites the protective coverage “4” of the FEC packet for the data packet 4 as the protective coverage “3.” The node #2 rewrites the sequence number “1” of the FEC packet for the data packet 4 to the sequence number “3.” The node #2 then re-generates the FEC packet 3 using the data packet 4, the data packet 9, and the data packet 10.

The FEC packet information is thus modified, and the FEC packet is re-generated. The node #2 transmits to the node #3 the data packets 1-3, the data packet 5, the FEC packet 1, the data packets 6-8, the FEC packet 2, the data packet 4, the data packets 9-10, . . . in that order.

The data packet 3 and the data packet 4 may be lost between the node #2 and the node #3. In the related art technique illustrated in FIG. 27, the node #3 needs a retransmission and the data packet 4 is transfer-delayed by a period from time T_{H} to time T_{J} equal to a length of 11 packets.

In accordance with the second embodiment, the data packet 4 is introduced into the FEC packet 3 that results from XOR gating the data packet 9 and the data packet 10 close in the order of reception at the node #2. For this reason, even if the data packet 3 and the data packet 4 are lost, the error correction capability of the FEC packet 1 and the FEC packet 3 is not exceeded. The node #3 recovers the data packet 3 using the FEC packet 1, and recovers the data packet 4 using the FEC packet 3. The transfer delay of the data packet is reduced to a period from T_{N} to T_{P} equal to a length of 4 packets.

Even if retransmission changes the transfer order of the data packet 4, out of the data packets 1-4 protected by the same FEC packet 1, the protective coverage of the FEC packet is reorganized such that the data packets close to each other in the transmission order to a lower-layer node fall within the same protective coverage. Even if packet losses are repeated between different nodes, the possibility of an increase in the transfer delay is reduced.

### Third Embodiment

In accordance with the second embodiment, the packet loss is quickly detected by adding the additional sequence number as the FEC packet information to the data packet. The transfer apparatus is not limited to this method. The packet loss may be detected using another method. In accordance with a third embodiment, the packet loss is detected by adding the sequence number of the data packet protected by the FEC packet within the protective coverage of the FEC packet.

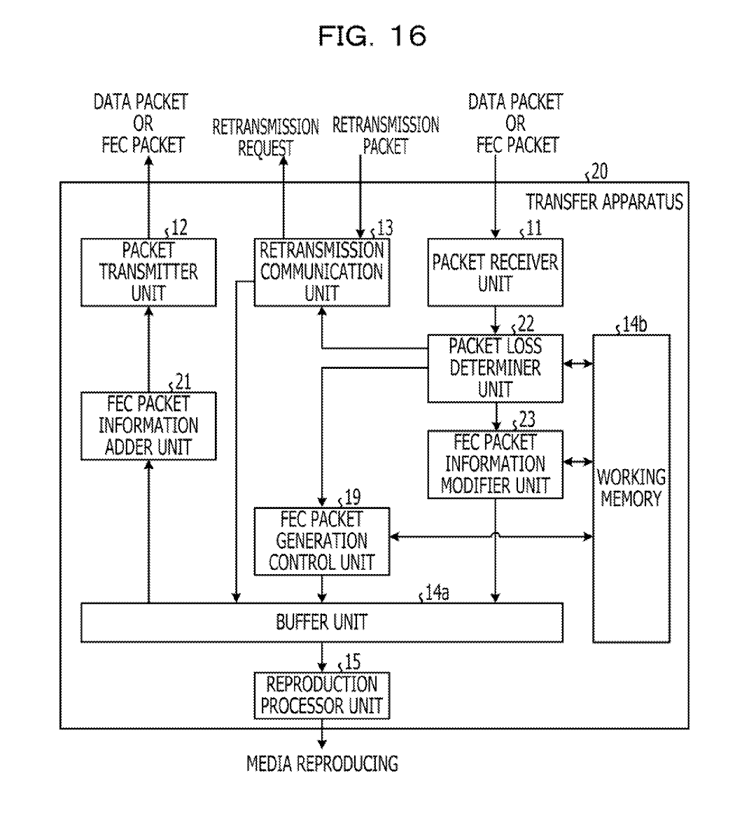

FIG. 16 is a block diagram illustrating a configuration of a transfer apparatus 20 of the third embodiment. An FEC packet information adder unit 21, a packet loss determiner unit 22, and an FEC packet information modifier unit 23 are partially different in function from the counterparts thereof in the transfer apparatus 10 of FIG. 7. The transfer apparatus 20 of FIG. 16 is discussed below in comparison with the transfer apparatus 10 of FIG. 7. Elements identical in function to those of the second embodiment are designated with the same reference numerals and the discussion thereof is omitted.

In comparison with the FEC packet information adder unit 16 of FIG. 7, the FEC packet information adder unit 21 adds the sequence number of the data packet protected by the FEC packet within the protective coverage of the FEC packet in place of the additional sequence number.

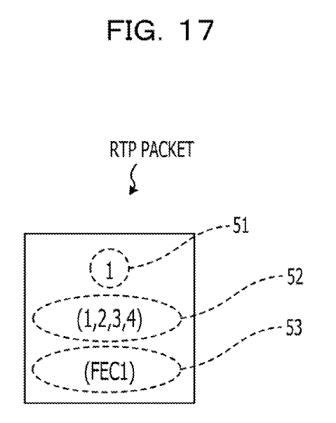

FIG. 17 illustrates an example of the FEC packet information included in the RTP packet. As illustrated in FIG. 17, the FEC packet information is encapsulated in the RTP packet denoted as a parcel. A sequence number 51 is assigned to the data packet when media data is packetized. A protective coverage 52 of the RTP packet is provided by the FEC packet. FIG. 17 also shows a sequence number 53 of the FEC packet.

As illustrated in FIG. 17, the sequence number of the RTP packet is “1,” and the sequence number of the FEC packet protecting the RTP packet is “1.” As illustrated in FIG. 17, the FEC packet protects the data packet 1, the data packet 2, the data packet 3, and the data packet 4. If the sequence numbers of the data packets protected by the FEC packet are assigned, a node at the receiver side can learn that the number of RTP packets protected by the FEC packet is “4.”

The packet loss determiner unit 22 is different from the packet loss determiner unit 17 of FIG. 7 in that the packet loss determiner unit 22 compares the protective coverage of the FEC packet written on the RTP header of the currently received data packet with the protective coverage of the FEC packet of the immediately preceding received data packet. More specifically, the packet loss determiner unit 22 compares the sequence number group of the data packet written on the currently received data packet with the sequence number group of the data packet of the immediately preceding data packet. If the two sequence number groups match each other, the packet loss determiner unit 22 determines that no packet loss has taken place. If the two sequence number groups fail to match each other, the packet loss determiner unit 22 determines that a packet loss has taken place.

The FEC packet information modifier unit 23 modifies the FEC packet information in the same manner as the FEC packet information modifier unit 18 of FIG. 7 if a packet loss takes place, if a data packet is recovered, or if a retransmitted data packet is received. On the other hand, the FEC packet information modifier unit 23 is different from the FEC packet information modifier unit 18 of FIG. 7 in that the FEC packet information modifier unit 23 always modifies both the protective coverage of the FEC packet and the sequence number of the FEC packet in the modification of the FEC packet information.

Process Flow

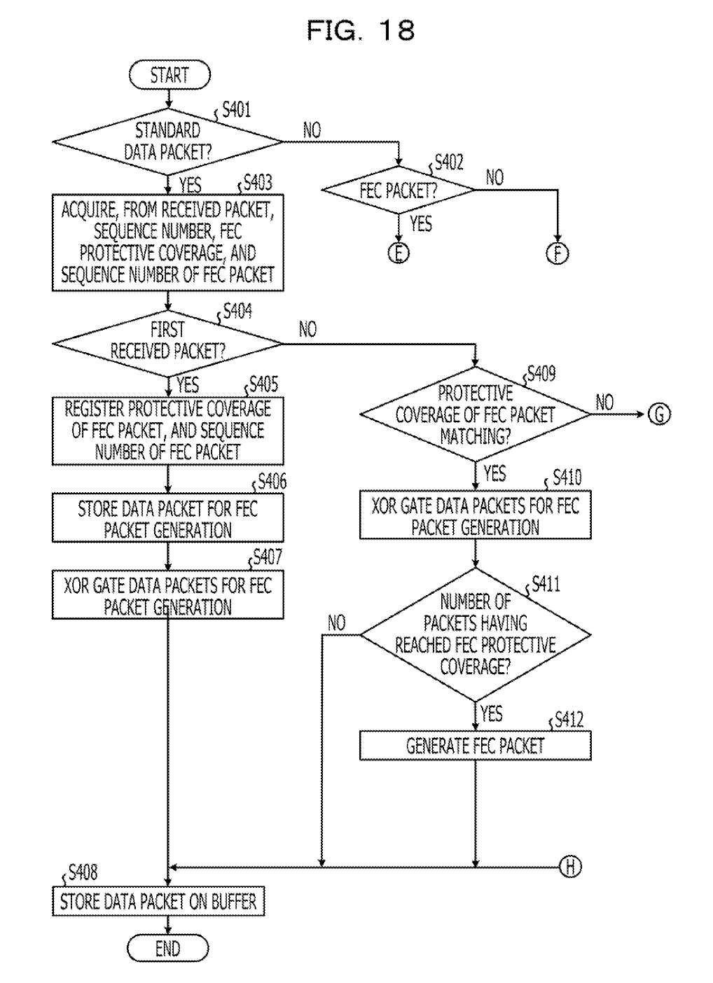

The process flow of the transfer apparatus 20 of the third embodiment is described below. FIGS. 18-21 are a flowchart of the packet reception process of the third embodiment. The process flow is initiated if one of the packet receiver unit 11 and the retransmission communication unit 13 receives a packet.

A packet is received from an upper-layer node as illustrated in FIG. 18. The packet loss determiner unit 22 determines whether the received packet is a standard data packet rather than a retransmitted packet (S401).

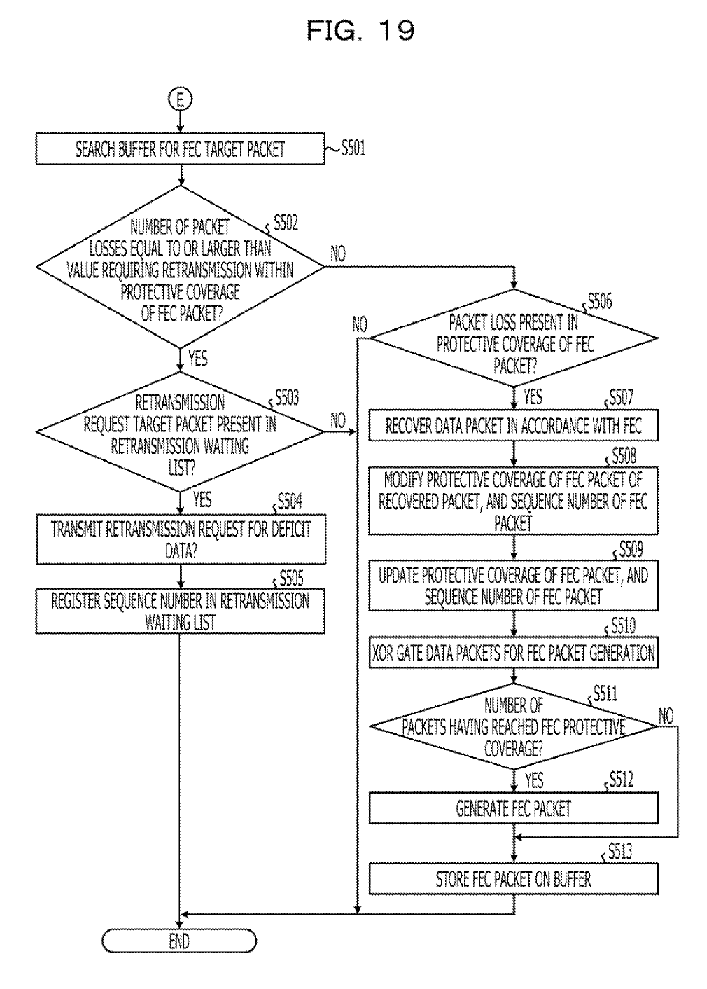

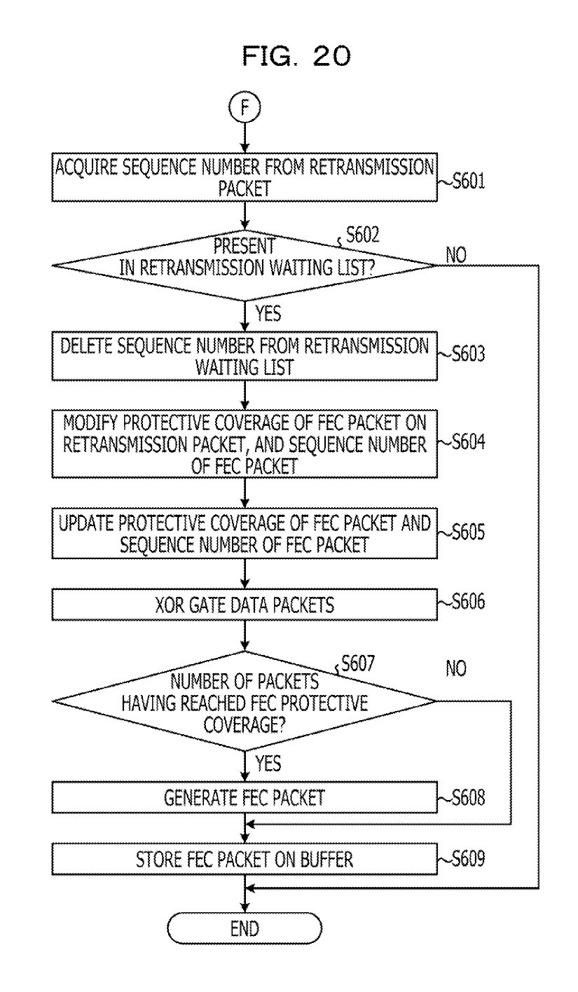

If the received packet is a standard data packet (yes from S401), the data packet reception process from S403 to S424 of FIG. 18 is performed. If the received packet is not a standard data packet but an FEC packet (no from S401 and yes from S402), an FEC packet reception process from S501 to S513 of FIG. 19 is performed. If the received packet is neither a standard data packet nor an FEC packet, but is a retransmitted packet (no from S401 and no from S402), a retransmission packet reception process from S601 to S609 of FIG. 20 is performed.

The data packet reception process is discussed. If the received packet is a standard data packet (yes from S401), the packet loss determiner unit 22 acquires the FEC packet information written on the RTP header of the data packet (S403). For example, the packet loss determiner unit 22 acquires, as the FEC packet information, the sequence number of the data packet, the protective coverage of the FEC packet, and the sequence number of the FEC packet.

The packet loss determiner unit 22 determines whether the data packet is a first received packet (S404). If the data packet is a first received packet (yes from S404), the packet loss determiner unit 22 performs a process described below. The packet loss determiner unit 22 registers on the working memory 14b the FEC packet information including the protective coverage of the FEC packet, and the sequence number of the FEC packet (S405).

The packet loss determiner unit 22 makes a copy of the data packet to generate an FEC packet, separately from the data packet to be transferred to a lower-layer node, and then stores the copy of the data packet on the buffer unit 14a (S406). The FEC packet generation control unit 19 XOR gates the currently received data packet (S407). The FEC packet generation control unit 19 stores on the buffer unit 14a the currently received data packet as a data packet to be transferred (S408), and ends the process.

If the data packet is not a first received packet (no from S404), the packet loss determiner unit 22 performs a process described below. The packet loss determiner unit 22 determines the protective coverage of the FEC packet written on the RTP header of the currently received the data packet matches the protective coverage of the FEC packet on the immediately preceding received data packet (S409). The sequence number groups of the data packets, as the protective coverage of the FEC packet, are checked against each other.

If the protective coverage matches the counterpart thereof (yes from S409), the FEC packet generation control unit 19 XOR gates the currently received data packet (S410).

The FEC packet generation control unit 19 determines whether the sequence number of the XOR gated data packet matches the protective coverage of the FEC packet stored on the working memory 14b (S411). If the sequence number of the XOR gated data packet matches the protective coverage of the FEC packet, i.e., the protective coverage of the FEC packet has been reached (yes from S411), the FEC packet generation control unit 19 generates an FEC packet from the data packets heretofore XOR gated (S412).

The FEC packet generation control unit 19 stores on the buffer unit 14a the generated FEC packet together with the data packet received by the packet receiver unit 11 (S408). Processing thus ends.

If the sequence number of the XOR gated data packet does not match the protective coverage of the FEC packet stored on the working memory 14b (no from S411), the FEC packet generation control unit 19 stores on the buffer unit 14a the currently generated FEC packet together with the data packet received by the packet receiver unit 11 (S408) and ends the processing.

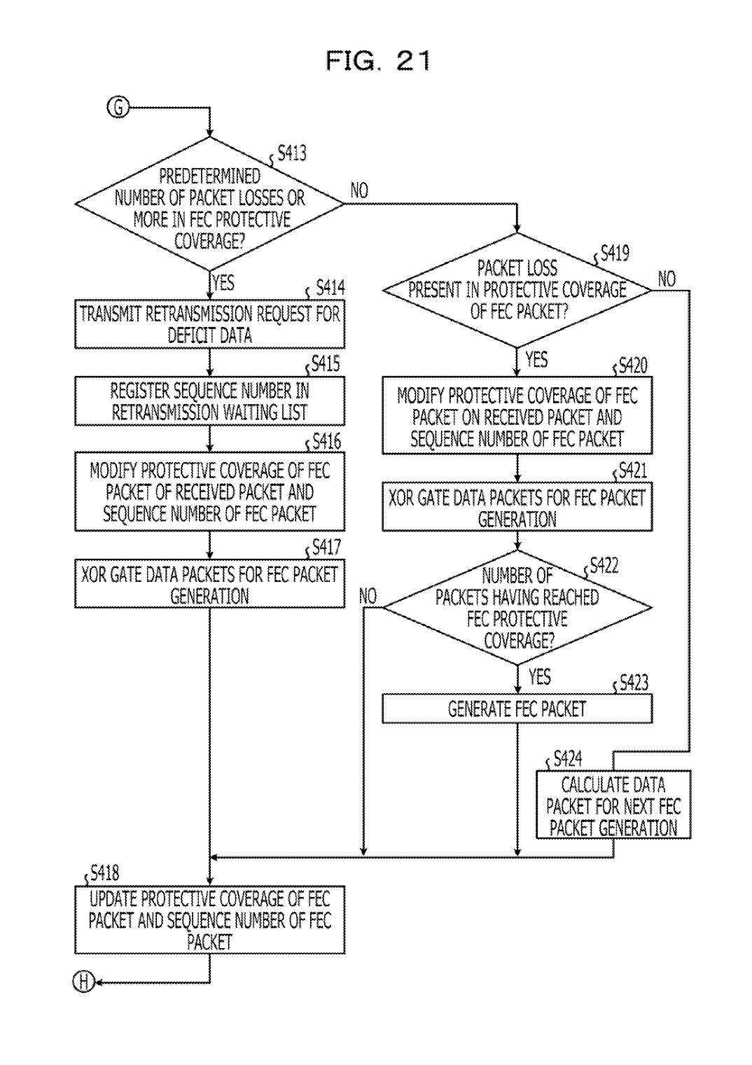

If the protective coverage fails to match the counterpart thereof (no from S409), data packet reception processing from operations S413 to S424 illustrated in FIG. 21 is performed. The packet loss determiner unit 22 performs a process described below. The packet loss determiner unit 22 determines whether the packet loss count has reached the value requiring retransmission within the protective coverage stored on the working memory 14b (S413).

If the packet loss count has reached the value requiring retransmission (yes from S413), the packet loss determiner unit 22 performs a process described below. The packet loss determiner unit 22 causes the retransmission communication unit 13 to transmit a retransmission request of a predetermined number of data packets (S414). The retransmission request requests the data packets to be transmitted starting with a data packet having the smallest sequence number. The packet loss determiner unit 22 then registers, in the retransmission waiting list stored on the working memory 14b, information related to the retransmission-requested data packet, for example, the sequence number of the data packet (S415).

The FEC packet information modifier unit 23 modifies the protective coverage of the FEC packet and the sequence number of the FEC packet written on the RTP header of the received data packet to the counterparts thereof stored on the working memory 14b (S416). The FEC packet generation control unit 19 XOR gates the currently received data packet (S417).

The packet loss determiner unit 22 updates the FEC packet information stored on the working memory 14b to the protective coverage of the FEC packet and the sequence number of the FEC packet on the currently received data packet (S418).

If the packet loss count has not reached the value requiring retransmission (no from S413), the packet loss determiner unit 22 determines whether any packet loss takes place within the protective coverage stored on the working memory 14b (S419).

If any packet loss takes place within the protective coverage (yes from S419), the FEC packet information modifier unit 23 performs a process described below. The FEC packet information modifier unit 23 modifies the protective coverage of the FEC packet and the sequence number of the FEC packet written on the RTP header of the received data packet to the counterparts thereof stored on the working memory 14b (S420).

The FEC packet generation control unit 19 XOR gates the currently received data packet (S421). The FEC packet generation control unit 19 determines whether the sequence number of the XOR gated data packet matches the protective coverage of the FEC packet stored on the working memory 14b (S422). If the sequence number of the XOR gated data packet matches the protective coverage of the FEC packet, i.e., the protective coverage of the FEC packet has been reached (yes from S422), the FEC packet generation control unit 19 generates an FEC packet from the data packets heretofore XOR gated (S423).

The FEC packet generation control unit 19 stores on the buffer unit 14a the generated FEC packet together with the data packet received by the packet receiver unit 11 (S408). Processing thus ends.

If no packet loss is found within the protective coverage (no from S419), the packet loss determiner unit 22 calculates a data packet for use in generation of a next FEC packet (S424).

The packet loss determiner unit 22 updates the FEC packet information stored on the working memory 14b to the protective coverage and the sequence number of the FEC packet that is currently received (S418). The updated data is stored on the packet buffer (S408). Processing thus ends.

The FEC packet reception process is discussed further with reference to FIG. 19. If an FEC packet has been received (yes from S402), the packet loss determiner unit 22 searches the buffer unit 14a for the data packet corresponding to the sequence number of the data packet protected by the currently received FEC packet (S501).

The packet loss determiner unit 22 determines whether the packet loss count has reached a value requiring retransmission within the protective coverage of the FEC packet written on the currently hit data packet (S502).

If the packet loss count has reached the value requiring retransmission (yes from S502), the packet loss determiner unit 22 performs a process described below. The packet loss determiner unit 22 determines whether the lost data packet, i.e., the packet as a retransmission request target is registered in a retransmission waiting list stored on the working memory 14b (S503). If the lost packet data is registered in the retransmission waiting list (no from S503), processing thus ends.

If the lost packet data is unregistered in the retransmission waiting list (yes from S503), the packet loss determiner unit 22 performs a process described below. The packet loss determiner unit 22 causes the retransmission communication unit 13 to transmit a retransmission request of a specific number of data packets (S504). The retransmission request requests the data packets to be transmitted starting with a data packet having the smallest sequence number. The packet loss determiner unit 22 then registers, in the retransmission waiting list stored on the working memory 14b, information related to the retransmission-requested data packet, for example, the sequence number of the data packet (S505). Processing thus ends.

If the packet loss count has not reached the value requiring retransmission (no from S502), the packet loss determiner unit 22 performs a process described below. The packet loss determiner unit 22 determines whether any packet loss is present in the protective coverage of the FEC packet written on the currently hit data packet (S506).

If no packet loss is present (no from S506), processing ends. If a packet loss is present (yes from S506), the FEC packet generation control unit 19 recovers the lost data packet using the currently received FEC packet (S507).

The FEC packet information modifier unit 23 modifies the protective coverage of the FEC packet and the sequence number of the FEC packet written on the RTP header of the recovered data packet to the counterparts thereof stored on the working memory 14b (S508).

The packet loss determiner unit 22 updates the FEC packet information stored on the working memory 14b to the protective coverage of the FEC packet, and the sequence number of the FEC packet on the currently recovered data packet (S509).

The FEC packet generation control unit 19 XOR gates the recovered data packet (S510). The FEC packet generation control unit 19 determines whether the sequence number of the XOR gated data packet matches the protective coverage of the FEC packet stored on the working memory 14b (S511). If the sequence number of the XOR gated data packet matches the protective coverage of the FEC packet, i.e., the protective coverage of the FEC packet has been reached (yes from S511), the FEC packet generation control unit 19 generates an FEC packet from the data packets heretofore XOR gated (S512).

The FEC packet generation control unit 19 stores on the buffer unit 14a the generated FEC packet together with the currently restored data packet (S513). Processing thus ends.

If the protective coverage of the FEC packet has not been reached (no from S511), the FEC packet generation control unit 19 stores the currently recovered data packet on the buffer unit 14a (S513). Processing thus ends.

The retransmission packet reception process is described below with reference to FIG. 20. If a retransmitted data packet is received (no from S402), the packet loss determiner unit 22 acquires the sequence number of the data packet written on the RTP header of the retransmitted data packet (S601).

The packet loss determiner unit 22 determines whether the sequence number of the retransmitted data packet is registered in the retransmission waiting list on the working memory 14b (S602). If the sequence number is not registered in the retransmission waiting list (no from S602), processing ends.

If the sequence number is registered in the retransmission waiting list (yes from S602), the packet loss determiner unit 22 deletes the sequence number of the retransmitted data packet from the retransmission waiting list (S603).

The FEC packet information modifier unit 23 modifies the protective coverage of the FEC packet and the sequence number of the FEC packet written on the RTP header of the retransmitted data packet to the counterparts thereof written on the working memory 14b (S604).

The packet loss determiner unit 22 updates the FEC packet information stored on the working memory 14b to the protective coverage of the FEC packet and the sequence number of the FEC packet on the retransmitted data packet (S605).

The FEC packet generation control unit 19 XOR gates the retransmitted data packet (S606). The FEC packet generation control unit 19 determines whether the sequence number of the XOR gated data packet matches the protective coverage of the FEC packet stored on the working memory 14b (S607). If the sequence number of the XOR gated data packet matches the protective coverage of the FEC packet (yes from S607), the FEC packet generation control unit 19 generates an FEC packet from the data packets heretofore XOR gated (S608).

The FEC packet generation control unit 19 stores on the buffer unit 14a the currently generated FEC packet together with the currently recovered data packet (S609). Processing thus ends.

If the protective coverage of the FEC packet has not been reached (no from S607), the FEC packet generation control unit 19 stores the currently recovered data packet on the buffer unit 14a (S608). Processing thus ends.

Advantages of the Third Embodiment

When the data packet is received, the transfer apparatus 20 of the third embodiment determines the packet loss of the data packet using the sequence number of the data packet included in the data packet. In response to the packet loss determination results, the transfer apparatus 20 of the third embodiment places the retransmission request of the data packet to an upper-layer node, and then receives a retransmitted data packet. The transfer apparatus 20 of the third embodiment updates the FEC packet information of the data packets in the order of reception of the data packets including the data packet retransmitted and then received. The transfer apparatus 20 of the third embodiment controls the transfer delay caused with the data packet transferred at a variable bit rate while reducing and/or minimizing a change in the header information of the data packet such as the RTP packet, for example.

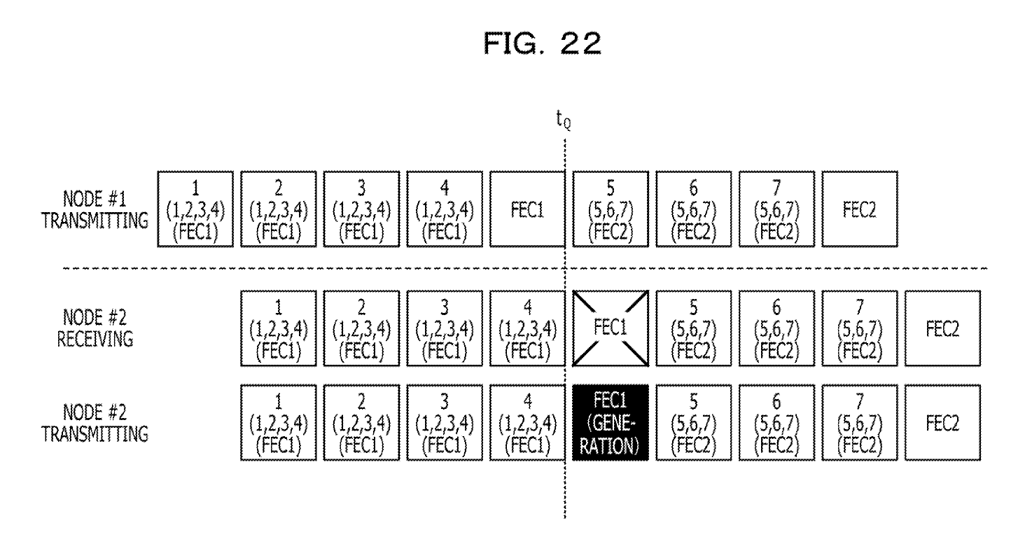

Those advantages are described with reference a transfer example. FIG. 22 illustrates an example of data transfer by the transfer apparatus 20 of the third embodiment. As illustrated in FIG. 22, data is transferred from a node #1 to a node #2. FIG. 22 illustrates sequence numbers assigned to data packets, and protective coverage, and sequence numbers assigned to the FEC packets, each packet diagrammatically denoted by a parcel. Data packets 1-4 are protected through the error correction of an FEC packet 1, and data packets 5-7 are protected through the error correction of an FEC packet 2. In FIG. 22, the number of packets recovered by an FEC packet is one.

Referring to FIG. 22, the FEC packet information adder unit 16 of the node #1 attaches the protective coverage of the FEC packet to each of the data packets. For example, an FEC packet 1 is constructed of the data packets 1-4, and the packet number of “4, 3, 2, 1” protected by the FEC packet 1 is attached to the FEC packet 1 as a protective coverage of the FEC packet for the data packets 1-4. The FEC packet information adder unit 16 of the node #1 also attaches to each data packet the sequence number assigned to the FEC packet. The FEC packet information adder unit 21 in each of the node #2 and subsequent nodes does not add the FEC packet information because the FEC packet information is already added.

When the FEC packet information is added, the sequence number of the data packet protected by the FEC packet is added to the field “FEC Coverage” and the FEC sequence number is added to the field “FEC ID” as illustrated in FIG. 8 on a per data packet basis. The field “Additional Sequence Number” of FIG. 8 is not used in the third embodiment. The fields “SN Base” and “Mask” of the FEC packet header are set in accordance with the sequence number of the data packet. For example, the fields are set to be “SN Base: 1 and Mask: 0xF00000” for the FEC packet 1. In this case, upper 4 bits are a protective target.

As illustrated in FIG. 22, the node #1 transfers to the node #2 the data packets 1-4, the FEC packet 1, the data packets 5-7, and the FEC packet 2 in that order. The FEC packet 1 may be assumed to be lost between the node #1 and the node #2. In this case, the node #2 receives from the node #1 the data packets 1-4, the data packets 5-7, and the FEC packet 2 in that order.

The node #2 XOR gates the data packets each time each of the data packets 1-4 is received. At time T_{Q} the protective coverage “4” of the FEC packet is reached, the calculation of the parity information of the FEC packet 1 is complete. Regardless of whether the FEC packet 1 is lost between the node #1 and the node #2, the node #2 can re-generate an FEC packet 1 and transmit the FEC packet 1 to a lower-layer node. The FEC packet 1 is transferred to a lower-layer node without the need for detecting the loss of the FEC packet 1. The third embodiment thus reduces the possibility that the data transfer continues to a lower-layer node with the FEC packet 1 lost, and thus controls an increase in the transfer delay due to the loss of the FEC packet.

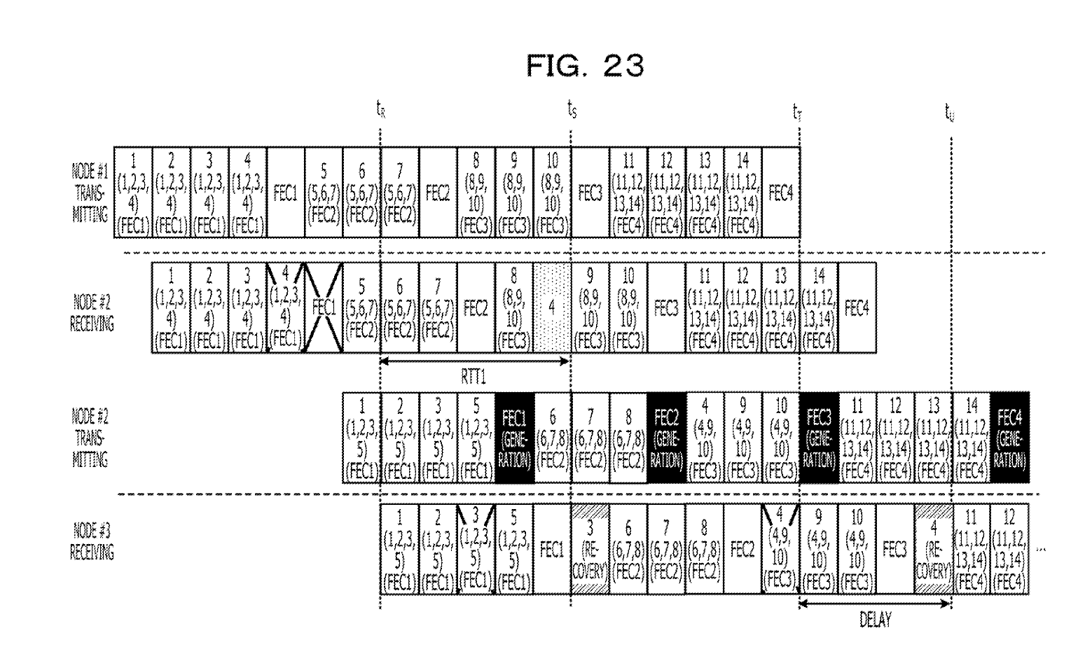

FIG. 23 illustrates an example of the data transfer of the transfer apparatus of the third embodiment. As illustrated in FIG. 23, a node #1, a node #2, and a node #3 perform the data transfer in that order. FIG. 23 illustrates sequence numbers assigned to data packets, and protective coverage, and sequence numbers assigned to the FEC packets, each packet diagrammatically denoted by a parcel. Data packets 1-4 are protected through the error correction of an FEC packet 1, data packets 5-7 are protected through the error correction of an FEC packet 2, and data packets 8-10 are protected through the error correction of an FEC packet 3. Data packets 11-14 are protected through the error correction of an FEC packet 4. In FIG. 23, the number of packets recovered by an FEC packet is one.

Referring to FIG. 23, the node #2 detects the loss of the data packet 4 and the FEC packet 1 because the protective coverage “5, 6, 7” of the data packet 5 fails to match the protective coverage “1, 2, 3, 4” of the data packet 3 at time T_{R} at which the data packet 5 is received. Since the packet loss exceeds the error correction capability of the FEC packet, the node #2 transmits to the node #1 a retransmission request of the data packet 4 at time T_{R}. The retransmission-requested data packet 4 reaches the node #2 at time T_{S} at which round trip time (RTT) 1 between the node #1 and the node #2 has elapsed.

The node #2 operates in a manner different from the related art technique of FIG. 27 in which the FEC packet 1 is generated by XOR gating the data packets 1-4 in response to the reception of the retransmitted data packet 4.

More specifically, the node #2 requests the node #1 to retransmit the data packet 4. The node #2 then modifies the protective coverage of the FEC packet on the data packets 1-3 from “1,2,3,4” to “1,2,3,5.” The node #2 modifies the protective coverage of the FEC packet on the data packet 5 from “5,6,7” to “1,2,3,5.” The node #2 modifies the sequence number of the FEC packet on the data packet 5 from “FEC2” to “FEC1.” The node #2 further generate the FEC packet 1 in accordance with the data packets 1-3 and the data packet 5. The calculation of the XOR gating of the data packets 1-3 is already complete at time T_{R} at which the data packet 5 is received. The node #2 XOR gates the calculation results and the data packet 5, thereby re-generating the FEC packet 1. The FEC header has “SN Base:1 and Mask: 0xE80000.” The node #2 starts transmitting the packets to the node #3 in response to the completion of the generation of the FEC packet 1.

The node #2 successively modifies the protective coverage of the FEC packet and the sequence number of the FEC packet on the data packet 5. More specifically, the node #2 modifies the protective coverage of the FEC packet on the data packet 8 from “8,9,10” to “6,7,8” and the sequence number of the FEC packet on the data packet 8 from “FEC3” to “FEC2.” The node #2 generates the FEC packet 2 using the data packets 6-8. The received FEC packet 2 becomes unnecessary and is thus discarded. The FEC header has “SN Base: 6 and Mask: 0xE00000.”

The node #2 receives the retransmitted data packet 4 and waits in standby until the data packet 10 is received, because the immediately preceding received data packet 8 has a protective coverage of “8,9,10” of the FEC packet and a sequence number “FEC3” of the FEC packet. The node #2 then modifies the protective coverage of the FEC packet on the data packet 4 from “1,2,3,4” to “4,9,10” and the sequence number of the FEC packet from “FEC1” to “FEC3.” The node #2 further modifies the protective coverage of the FEC packet on the data packets 9-10 from “8,9,10” to “4,9,10.” The node #2 instructs the FEC packet 3 to be generated in accordance with the data packet 4, and the data packets 9 and 10. The FEC header has “SN Base: 4 and Mask: 0x860000” at this point of time.

In accordance with the third embodiment, the data packet 4 is introduced into the FEC packet 3 that results from XOR gating the data packet 9 and the data packet 10 close in the order of reception at the node #2. For this reason, even if the data packet 3 and the data packet 4 are lost, the error correction capability of the FEC packet 1 and the FEC packet 3 is not exceeded. The node #3 recovers the data packet 3 using the FEC packet 1, and recovers the data packet 4 using the FEC packet 3. The transfer delay of the data packet is cut down to a period from T_{T} to T_{U} equal to a length of 4 packets.

Even if retransmission changes the transfer order of the data packet 4, out of the data packets 1-4 protected by the same FEC packet 1, the protective coverage of the FEC packet is reorganized such that the data packets close to each other in the transmission order to a lower-layer node fall within the same protective coverage. Even if packet losses are repeated between different nodes, the possibility of an increase in the transfer delay is reduced.

### Fourth Embodiment

The transfer apparatuses of the embodiments have been discussed above. However, the invention may be implemented in a variety of embodiments other than the above-described embodiments. Other example embodiments that fall within the scope of the invention are described below.

### ALTERNATIVE EMBODIMENTS

In accordance with the second embodiment, the number of data packets protected by the FEC packet is used as the information indicative of the protective coverage of the FEC packet. The transfer apparatus is not limited to this method. For example, the additional sequence number may be substituted for by the sequence number of a media data packet protected by the FEC packet and a distance to the FEC packet (information indicative of the number of packets present).

In the transfer apparatus, a recoverable packet count of the FEC packet, i.e., the error correction capability may be added to the RTP header. The timing of sending a retransmission request to an upper-layer node may thus be determined if a packet loss is detected.

### Applications

The elements in each transfer apparatus illustrated in the drawings are not necessarily physically configured as illustrated. The configuration of each transfer apparatus is not limited to the configuration illustrated in each of the drawings. The elements may be integrated or split in terms of function or physical structure by any unit depending on workload or usage. For example, the packet receiver unit 11, the packet transmitter unit 12, and the retransmission communication unit 13 are respectively function units, but these units in part or whole may be integrated into a unitary structure.

### Transfer Program

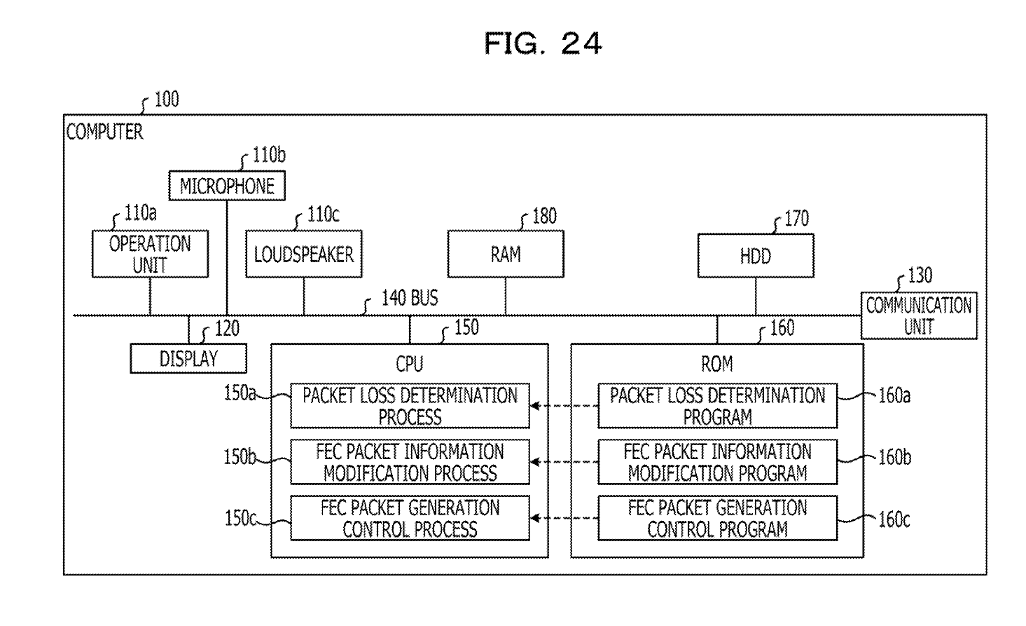

The above-described variety of processes may be performed by a computer such as a personal computer or a work station, which executes a prepared computer program. FIG. 24 illustrates a computer that executes a transfer program having the same function as the above-described embodiments.

FIG. 24 illustrates an example of a computer 100 that executes a transfer program of a fourth embodiment. The computer 100 includes operation unit 110a, microphone 110b, loudspeaker 110c, display 120, and communication unit 130. The computer 100 further includes central processing unit (CPU) 150, read-only memory (ROM) 160, hard disk drive (HDD) 170, and random-access memory (RAM) 180. These elements 110-180 are interconnected via a bus 140.

The ROM 160 pre-stores a control program having the same function as that of the packet loss determiner unit 17, the FEC packet information modifier unit 18, and the FEC packet generation control unit 19 of the second embodiment. As illustrated in FIG. 24, the ROM 160 stores a packet loss determination program 160a, FEC packet information modification program 160b, and FEC packet generation control program 160c. The programs 160a-160c may be integrated or split in the same manner as the elements in the transfer apparatus of FIG. 7. Data stored on the RAM 160 is not necessarily always stored on the RAM 160, and only needed data may be stored on the RAM 160, for example.

The CPU 150 reads and executes the programs 160a-160c. As illustrated in FIG. 24, the CPU 150 performs a packet loss determination process 150a, an FEC packet information modification process 150b, and an FEC packet generation process 150c in accordance with the programs 160a-160c. The processes 150a-150c may respectively correspond to the packet loss determiner unit 17, the FEC packet information modifier unit 18, and the FEC packet generation control unit 19 illustrated in FIG. 2. The units virtually implemented on the CPU 150 are not necessarily always operative on the CPU 150, and only a unit needed for a given process may be virtually implemented on the CPU 150, for example.

The CPU 150 executes the transfer program using the RAM 180, for example.

The data reproduction program is not necessarily stored on the HDD 170 or the ROM 160 from the start. For example, the program may be stored on a flexible disk loaded on the computer 100, for example, “movable physical media” including floppy disk, CD-ROM, DVD disk, magneto-optical disk, and IC card. The computer 100 may retrieve the program from one of these movable physical media and execute the program. Another computer or a server apparatus connected to the computer 100 via public telephone line, the Internet, local-area network (LAN), wide-area network (WAN), or the like may store the program, and the computer 100 may then retrieve the stored program for execution.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that the various changes, substitutions, and alterations could be made hereto without departing from the spirit and scope of the invention.

What is claimed is:

1. A transfer apparatus comprising:
a receiver to receive one of an error correction packet and a data packet, the error correction packet for recovering the data packet through error correction, and the data packet having protective coverage information written thereon, the protective coverage information identifying a protective coverage on the data packet recoverable through an error correction of the error correction packet;
an updater to update the protective coverage information in accordance with an order of reception of the data packets received by the receiver unit;
a generator to generate an error correction packet of the data packet identified by new protective coverage information updated by the updater unit; and
a transmitter to transmit the data packet having the protective coverage information updated by the updater unit, and the error correction packet generated by the generator unit.

2. The transfer apparatus according to claim 1, wherein the data packet has a transmission sequence number written thereon by a transmission source of the data packet, the transmission sequence number is attached in the order of transmission of the data packet,
wherein the transfer apparatus further comprises:
a determiner to determine a packet loss of the data packet in accordance with the transmission sequence number included in the data packet if the receiver receives the data packet;
a retransmission request unit to submit a retransmission request of the data packet to the transmission source of the packet in accordance with the determination results of the determiner concerning the packet loss; and
a retransmission receiver to receive the data packet retransmitted by the transmission source of the packet, and
wherein the updater updates the protective coverage information and the transmission sequence number on the data packet in accordance with the order of reception of the data packet received by the receiver and the retransmission receiver.

3. The transfer apparatus according to claim 1,
wherein the data packet has a sequence number written thereon by a transmission source of the data packet, the sequence number being the sequence number of the data packet protected by the error correction packet,
wherein the transfer apparatus further comprises:
a determiner to determine a packet loss of the data packet in accordance with the sequence number included in the data packet if the receiver unit receives the data packet;
a retransmission request unit to submit a retransmission request of the data packet to the transmission source of the packet in accordance with the determination results of the determiner concerning the packet loss; and
a retransmission receiver to receive the data packet retransmitted by the transmission source of the packet, and
wherein the updater updates the sequence number of the data packet written in the protective coverage information on the data packet and the transmission sequence number in accordance with the order of reception of the data packet received by the receiver and the retransmission receiver.

4. A computer-readable storage medium including a program to cause a transfer apparatus to execute a transfer method comprising:
receiving one of an error correction packet and a data packet, the error correction packet for recovering the data packet through error correction, and the data packet having protective coverage information written thereon, the protective coverage information identifying a protective coverage on the data packet recoverable through an error correction of the error correction packet;
updating the protective coverage information on the data packet in accordance with an order of reception of the data packets received in the receiving;
generating the error correction packet of the data packet identified by new protective coverage information, in response to the protective coverage information updated in the updating; and
transmitting the data packet having the protective coverage information updated in the updating, and the error correction packet generated in the generating.

5. A transfer method for causing a computer to transfer data, the transfer method comprising:
receiving one of an error correction packet and a data packet, the error correction packet for recovering the data packet through error correction, and the data packet having protective coverage information written thereon, the protective coverage information identifying a protective coverage on the data packet recoverable through an error correction of the error correction packet;
updating the protective coverage information on the data packet in accordance with an order of reception of the data packets received in the receiving;
generating the error correction packet of the data packet identified by new protective coverage information, in response to the protective coverage information updated in the updating; and
transmitting the data packet having the protective coverage information updated in the updating, and the error correction packet generated in the generating.
